(19) United States
(12) Patent Application Publication
(10) Pub. No.: US 2025/0254986 A1
(43) Pub. Date: Aug. 7, 2025

(54) SEMICONDUCTOR DEVICE AND METHOD FOR FABRICATING THE SAME

(71) Applicant: SAMSUNG ELECTRONICS CO, LTD., Suwon-si (KR)

(72) Inventors: Sun Ki MIN, Suwon-si (KR); Ji Eun LEE, Suwon-si (KR); Jeong Hyuk YIM, Suwon-si (KR)

(73) Assignee: SAMSUNG ELECTRONICS CO, LTD., Suwon-si (KR)

(21) Appl. No.: 18/889,963

(22) Filed: Sep. 19, 2024

(30) Foreign Application Priority Data
Feb. 2, 2024 (KR) 10-2024-0016494

(51) Int. Cl. H01L 27/092; H01L 21/8238; H01L 29/06; H01L 29/423; H01L 29/49; H01L 29/66; H01L 29/775; H01L 29/786

(52) U.S. Cl. CPC H10D 84/85; H10D 30/014; H10D 30/43; H10D 30/6735; H10D 30/6739; H10D 30/6757; H10D 62/121; H10D 64/017; H10D 84/0167; H10D 84/0181; H10D 84/038

(57) ABSTRACT

A semiconductor device includes a substrate including an N-type region and a P-type region, a first active pattern on the N-type region, a first gate structure on the N-type region, the first gate structure crossing the first active pattern and including fluorine (F), a second active pattern on the P-type region, and a second gate structure on the P-type region, the second gate structure crossing the second active pattern and including fluorine (F), where the first gate structure includes a first gate dielectric film on the first active pattern, and a first gate electrode on the first gate dielectric film, the second gate structure includes a second gate dielectric film on the second active pattern and a second gate electrode on the second gate dielectric film, and a fluorine (F) concentration of the second gate dielectric film is smaller than a fluorine (F) concentration of the first gate dielectric film.

### CROSS-REFERENCE TO RELATED APPLICATION

This application is based on and claims priority to Korean Patent Application No. 10-2024-0016494, filed on Feb. 2, 2024, in the Korean Intellectual Property Office, the disclosure of which is incorporated by reference herein in its entirety.

### BACKGROUND

Example embodiments of the disclosure relate to a semiconductor device and a method for fabricating the same.

A multi-gate transistor for forming an active pattern having a fin shape or a nanowire shape on a substrate and forming a gate on a surface of the active pattern has been suggested as a scaling technique for increasing a density of an integrated circuit.

Since this multi-gate transistor uses a three-dimensional channel, it may be easy to scale the multi-gate transistor. Also, even though a gate length of the multi-gate transistor is not increased, a current control capability may be improved. In addition, a short channel effect (SCE) in which a potential of a channel region is affected by a drain voltage may be suppressed effectively.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Provided are a semiconductor device with improved performance and reliability, and a method of fabricating the same.

Additional aspects will be set forth in part in the description which follows and, in part, will be apparent from the description, or may be learned by practice of the presented embodiments.

According to an aspect of an example embodiment, a semiconductor device may include a substrate including an N-type region and a P-type region, a first active pattern on the N-type region, a first gate structure on the N-type region, the first gate structure crossing the first active pattern and including fluorine (F), a second active pattern on the P-type region, and a second gate structure on the P-type region, the second gate structure crossing the second active pattern and including fluorine (F), where the first gate structure includes a first gate dielectric film on the first active pattern, and a first gate electrode on the first gate dielectric film, the second gate structure includes a second gate dielectric film on the second active pattern and a second gate electrode on the second gate dielectric film, and a fluorine (F) concentration of the second gate dielectric film is smaller than a fluorine (F) concentration of the first gate dielectric film.

According to an aspect of an example embodiment, a semiconductor device may include a substrate including a first region and a second region, a first transistor on the first region, the first transistor having a first threshold voltage, and a second transistor on the second region, the second transistor having a second threshold voltage lower than the first threshold voltage, where the first transistor includes a first active pattern and a first gate structure crossing the first active pattern, the first gate structure including fluorine (F), the second transistor includes a second active pattern and a second gate structure crossing the second active pattern, the second gate structure including fluorine (F), and a fluorine (F) concentration of the first gate structure is different from a fluorine (F) concentration of the second gate structure.

According to an aspect of an example embodiment, a semiconductor device may include a substrate, an active pattern on the substrate, and a gate structure on the substrate, the gate structure crossing the active pattern and including fluorine (F), where the gate structure includes a high dielectric film, a work function insulating film and a work function conductive film sequentially provided on the active pattern, and a fluorine (F) concentration of the high dielectric film and a fluorine (F) concentration of the work function conductive film are greater than a fluorine (F) concentration of the work function insulating film.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a semiconductor device according to one or more embodiments;

FIG. 2A depicts cross-sectional views taken along lines A1-A1, A2-A2 and A3-A3 of FIG. 1 according to one or more embodiments;

FIG. 2B depicts cross-sectional views taken along lines A4-A4, A5-A5 and A6-A6 of FIG. 1 according to one or more embodiments;

FIG. 3A depicts cross-sectional views taken along lines B1-B1, B2-B2 and B3-B3 of FIG. 1 according to one or more embodiments;

FIG. 3B depicts cross-sectional views taken along lines B4-B4, B5-B5 and B6-B6 of FIG. 1 according to one or more embodiments;

FIG. 4 depicts enlarged views illustrating a region R1, a region R2, a region R3, a region R4, a region R5 and a region R6 of FIGS. 2A and 2B, according to one or more embodiments;

FIGS. 5 to 10 are graphs illustrating a fluorine (F) concentration of a semiconductor device according to one or more embodiments;

FIGS. 11 to 13 are enlarged views illustrating further examples of a region R1, a region R2, a region R3, a region R4, a region R5 and a region R6 of FIGS. 2A and 2B, according to one or more embodiments;

FIGS. 14 to 28 are diagrams illustrating operations of a method for fabricating a semiconductor device according to one or more embodiments; and

FIGS. 29 and 30 are diagrams illustrating operations of a method for fabricating a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure.

In the disclosure, a multi-bridge channel field effect transistor (MBCFET™) that includes a multi-bridge channel of a nanosheet shape will be described as an example of a semiconductor device, but this is only an example. The person with ordinary skill in the art will understand that aspects of the present disclosure may be applied to a fin-type transistor (FinFET) including a channel of a fin shape, a transistor including a channel of a nanowire shape, a vertical FET (VFET), a complementary FET (CFET) or a three-dimensional (3D) transistor.

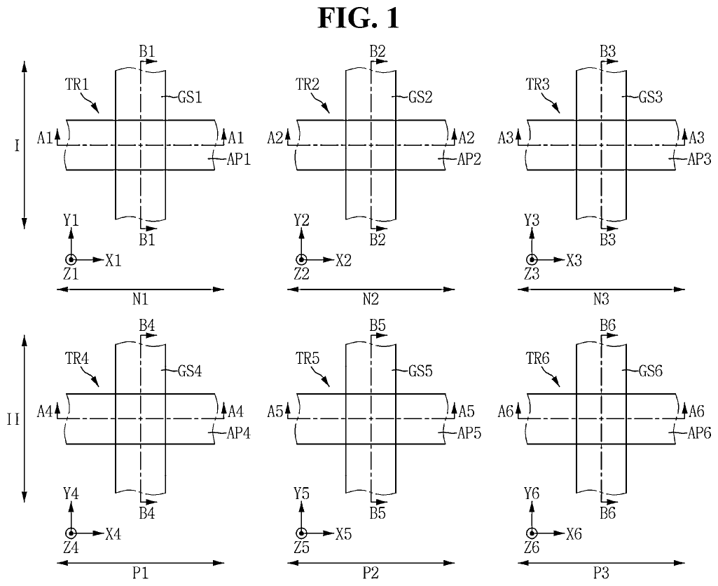

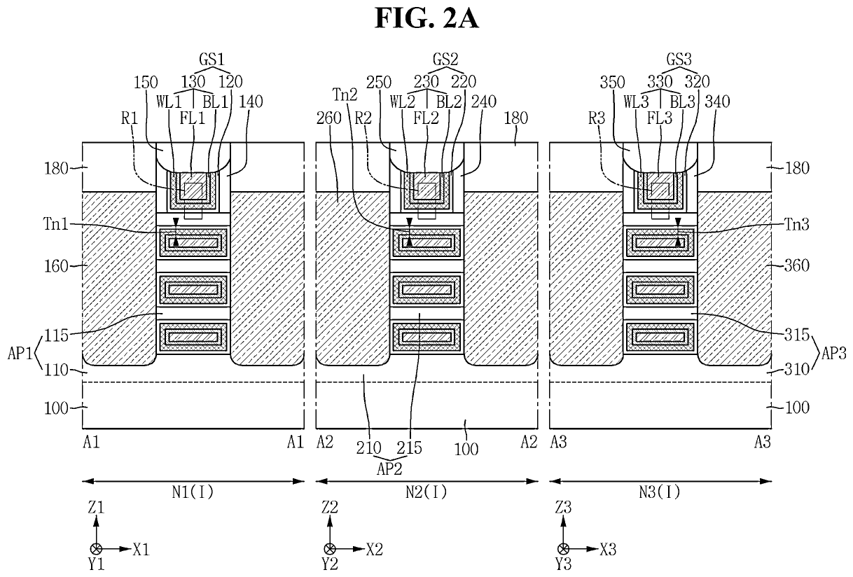

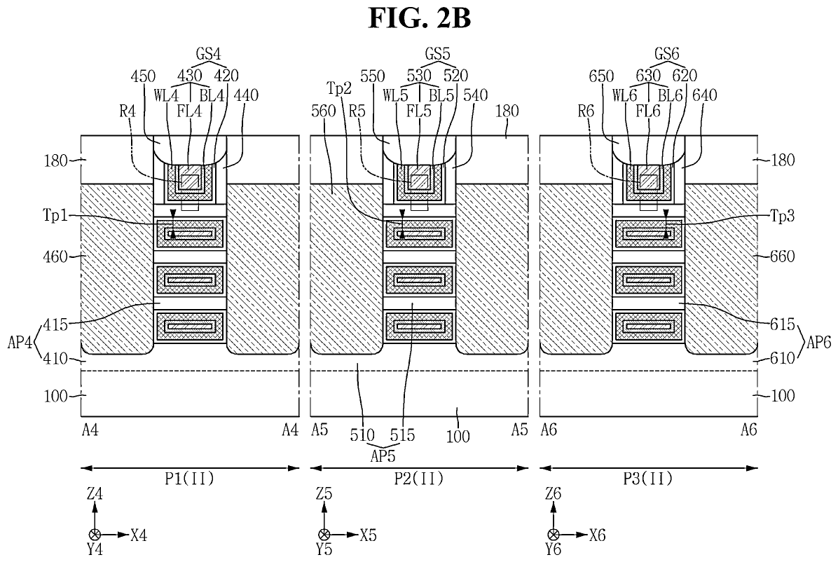

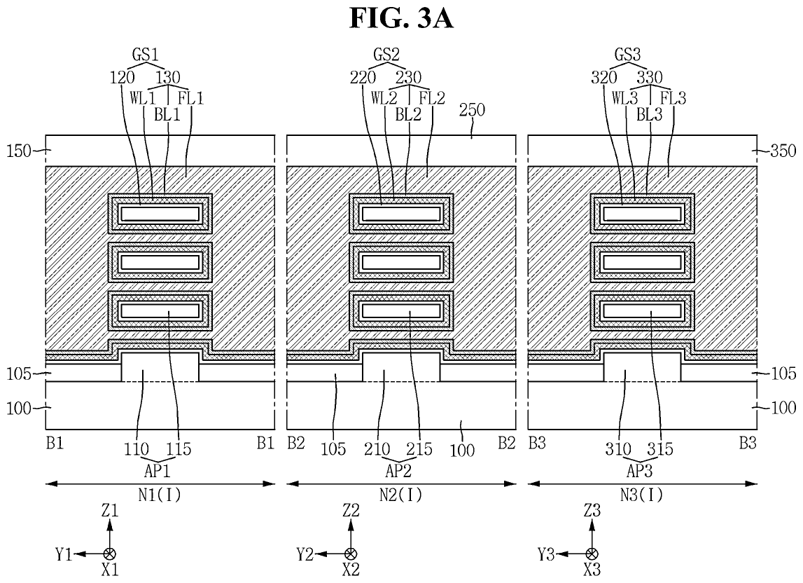

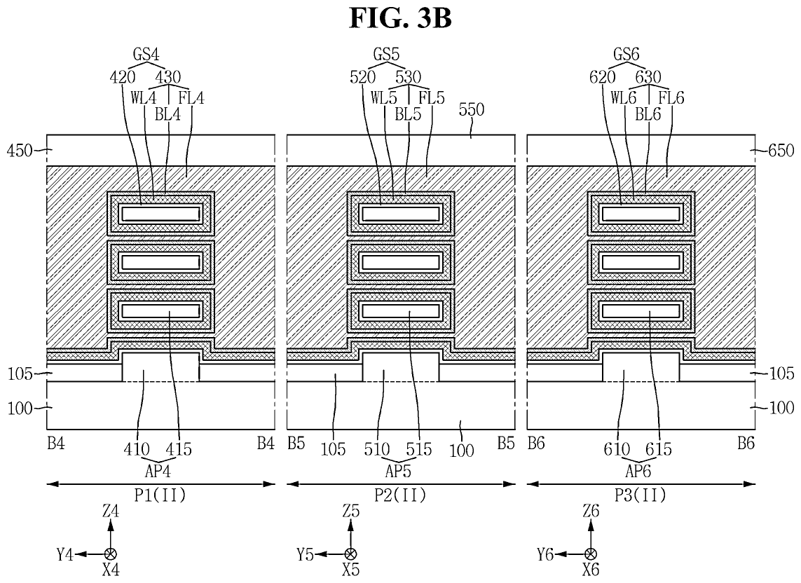

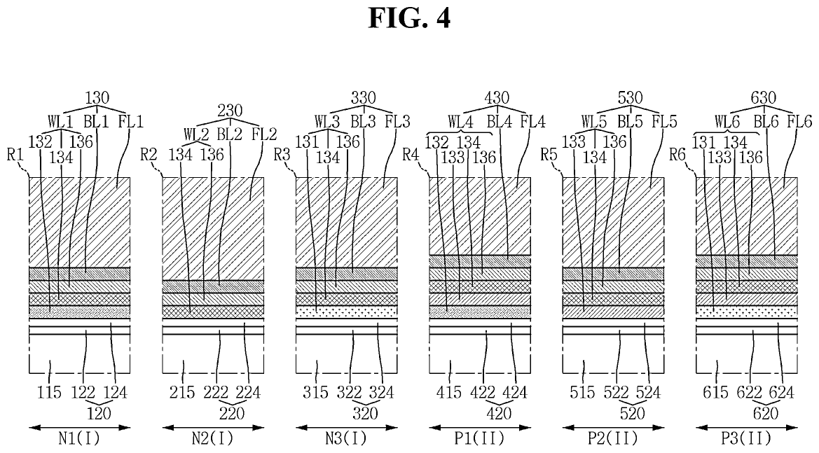

FIG. 1 is a diagram illustrating a semiconductor device according to one or more embodiments. FIG. 2A depicts cross-sectional views taken along lines A1-A1, A2-A2 and A3-A3 of FIG. 1 according to one or more embodiments. FIG. 2B depicts cross-sectional views taken along lines A4-A4, A5-A5 and A6-A6 of FIG. 1 according to one or more embodiments. FIG. 3A depicts cross-sectional views taken along lines B1-B1, B2-B2 and B3-B3 of FIG. 1 according to one or more embodiments. FIG. 3B depicts cross-sectional views taken along lines B4-B4, B5-B5 and B6-B6 of FIG. 1 according to one or more embodiments. FIG. 4 depicts enlarged views illustrating a region R1, a region R2, a region R3, a region R4, a region R5 and a region R6 of FIGS. 2A and 2B, according to one or more embodiments.

Referring to FIGS. 1 to 4, the semiconductor device according to one or more embodiments may include a substrate 100, a field insulating film 105, first to sixth active patterns AP1 to AP6, first to sixth gate structures GS1 to GS6, first to sixth gate spacers 140, 240, 340, 440, 540, and 640, first to sixth gate capping films 150, 250, 350, 450, 550 and 650, first to sixth source/drain patterns 160, 260, 360, 460, 560 and 660, and an interlayer insulating film 180.

The substrate 100 may be a bulk silicon or a silicon-on-insulator (SOI). The substrate 100 may be a silicon substrate, or may include other material, such as silicon germanium, silicon germanium on insulator (SGOI), indium antimonide, lead telluride, indium arsenide, indium phosphide, gallium arsenide or gallium antimonide, but is not limited thereto. Alternatively, the substrate 100 may have an epitaxial layer formed on a base substrate. In the following description, the substrate 100 may be a silicon substrate by way of example.

The substrate 100 may include an N-type region I and a P-type region II. An N-type FET may be formed on the N-type region I, and a P-type FET may be formed on the P-type region II. The N-type region I and the P-type region II may be regions adjacent to each other or regions spaced apart from each other.

The N-type region I may include first to third regions N1 to N3 different from one another. The first to third regions N1 to N3 may be regions adjacent to one another or spaced apart from one another. N-type transistors having different threshold voltages may be disposed on the first to third regions N1 to N3. For example, a first transistor TR1 having a first threshold voltage may be disposed on the first region N1, a second transistor TR2 having a second threshold voltage greater than the first threshold voltage may be disposed on the second region N2, and a third transistor TR3 having a third threshold voltage greater than the second threshold voltage may be disposed on the third region N3. For example, the first region N1 may be a super low threshold voltage (first threshold voltage) n-type transistor (SLVTN) region, the second region N2 may be a low threshold voltage (second threshold voltage greater than the first threshold voltage) n-type transistor (LVTN) region, and the third region N3 may be a regular threshold voltage (third threshold voltage greater than the second threshold voltage) n-type transistor (RVTN) region.

The P-type region II may include fourth to sixth regions P1 to P3 different from one another. The fourth to sixth regions P1 to P3 may be regions adjacent to one another or spaced apart from one another. P-type transistors having different threshold voltages may be disposed on the fourth to sixth regions P1 to P3. For example, a fourth transistor TR4 having a fourth threshold voltage may be disposed on the fourth region P1, a fifth transistor TR5 having a fifth threshold voltage smaller than the fourth threshold voltage may be disposed on the fifth region P2, and a sixth transistor TR6 having a sixth threshold voltage smaller than the fifth threshold voltage may be disposed on the sixth region P3. For example, the fourth region P1 may be a regular threshold voltage p-type (RVTP) region, the fifth region P2 may be a low threshold voltage p-type (LVTP) region, and the sixth region P3 may be a super low threshold voltage p-type (SLVTP) region.

The first to sixth transistors TR1 to TR6 may include first to sixth active patterns AP1 to AP6 and first to sixth gate structures GS1 to GS6, respectively. The first to sixth gate structures GS1 to GS6 may cross the first to sixth active patterns AP1 to AP6, respectively. For example, the first to sixth active patterns AP1 to AP6 may extend in directions X1 to X6, respectively, and the first to sixth gate structures GS1 to GS6 may extend in directions Y1 to Y6 crossing the directions X1 to X6, respectively. The directions X1 to X6 and the directions Y1 to Y6 may be parallel with an upper surface of the substrate 100, respectively.

Although the first to sixth transistors TR1 to TR6 are shown as being only arranged in the same direction, this is only an example, and the first to sixth transistors TR1 to TR6 may be arranged in different directions. For example, the directions X1 to X6 may be the same or different directions.

The first to sixth active patterns AP1 to AP6 may include first to sixth fin patterns 110, 210, 310, 410, 510 and 610 and at least one of first to sixth bridge patterns 115, 215, 315, 415, 515 and 615, respectively.

The first to sixth fin patterns 110, 210, 310, 410, 510 and 610 may protrude from the upper surface of the substrate 100 and extend in the directions X1 to X6, respectively. The first to sixth fin patterns 110, 210, 310, 410, 510 and 610 may be formed by etching a portion of the substrate 100, or may be epitaxial layers grown from the substrate 100.

At least one of the first to sixth bridge patterns 115, 215, 315, 415, 515 and 615 may be spaced apart from the upper surface of the substrate 100 and extend in the directions X1 to X6, respectively. For example, the first to sixth bridge patterns 115, 215, 315, 415, 515 and 615 may be spaced apart from the first to sixth fin patterns 110, 210, 310, 410, 510 and 610, respectively, in directions Z1 to Z6. The directions Z1 to Z6 may be perpendicular to the upper surface of the substrate 100. The first to sixth bridge patterns 115, 215, 315, 415, 515 and 615 may be used as channel regions of an MBCFET® including a multi-bridge channel. The number of bridge patterns included in each of the first to sixth bridge patterns 115, 215, 315, 415, 515 and 615 is only an example, and is not limited thereto.

Each of the first to sixth active patterns AP1 to AP6 may include silicon (Si) or germanium (Ge), which is an element semiconductor material. Alternatively, each of the first to sixth active patterns AP1 to AP6 may include a compound semiconductor, such as a group IV-IV compound semiconductor or a group III-V compound semiconductor. The group IV-IV compound semiconductor may be a binary or ternary compound, which includes at least two of carbon (C), silicon (Si), germanium (Ge) and tin (Sn), or a compound including at least two of carbon (C), silicon (Si), germanium (Ge) and tin (Sn), which are doped with a group IV element. The group III-V compound semiconductor may be, for example, one of a binary compound, a ternary compound or a quaternary compound, which is formed by combination of at least one of aluminum (A1), gallium (Ga) and indium (In), which is a group III element, and one of phosphorus (P), arsenic (As) and antimony (Sb), which are group V elements. In the following description, each of the first to sixth active patterns AP1 to AP6 is a silicon (Si) pattern by way of example.

The field insulating film 105 may be disposed on the substrate 100. For example, the field insulating film 105 may cover at least a portion of side surface of each of the first to sixth fin patterns 110, 210, 310, 410, 510 and 610. For example, an upper portion of each of the first to sixth fin patterns 110, 210, 310, 410, 510 and 610 may protrude more than an upper surface of the field insulating film 105. The field insulating film 105 may include at least one of, for example, silicon oxide, silicon nitride, silicon oxynitride and combinations thereof, but is not limited thereto.

The first to sixth gate structures GS1 to GS6 may be formed on the substrate 100, the field insulating film 105 and the first to sixth fin patterns 110, 210, 310, 410, 510 and 610, respectively. The first to sixth gate structures GS1 to GS6 may surround the peripheries of the first to sixth bridge patterns 115, 215, 315, 415, 515 and 615, respectively. That is, the first to sixth bridge patterns 115, 215, 315, 415, 515 and 615 may respectively extend in the directions X1 to X6 to pass through the first to sixth gate structures GS1 to GS6.

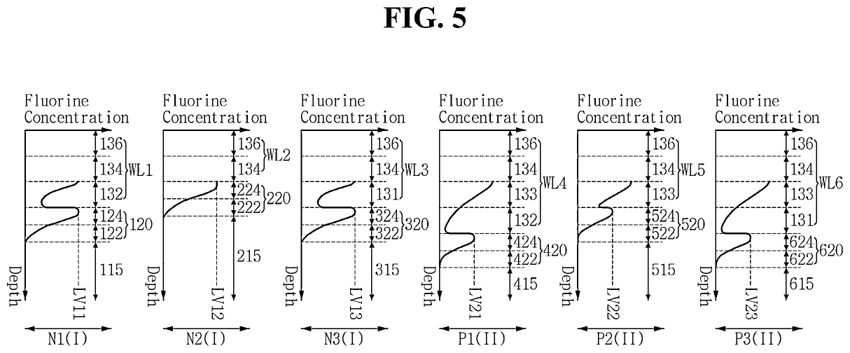

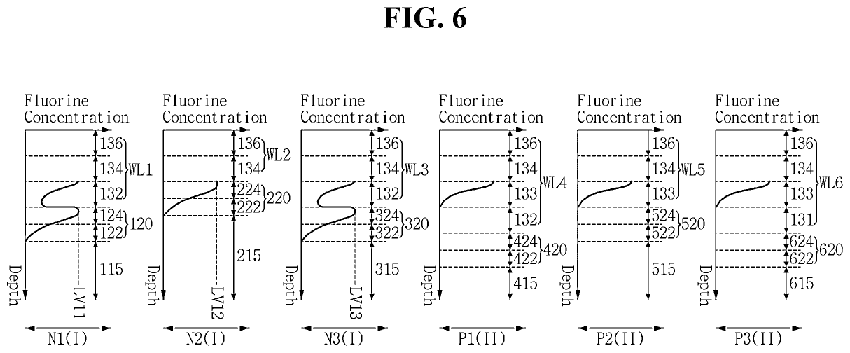

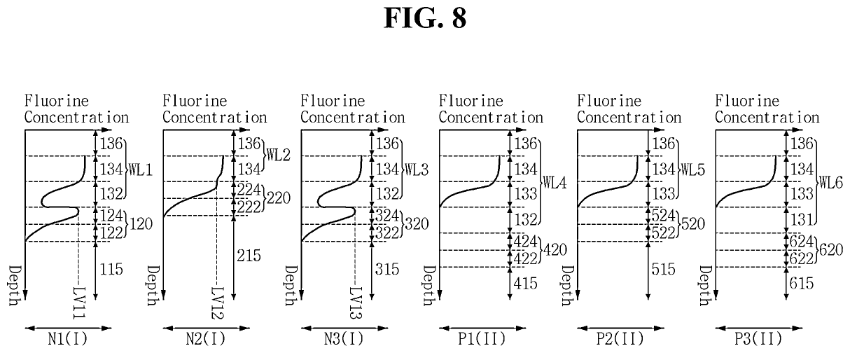

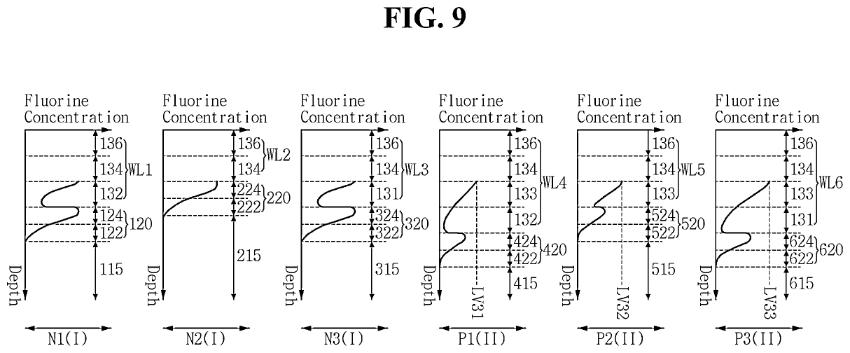

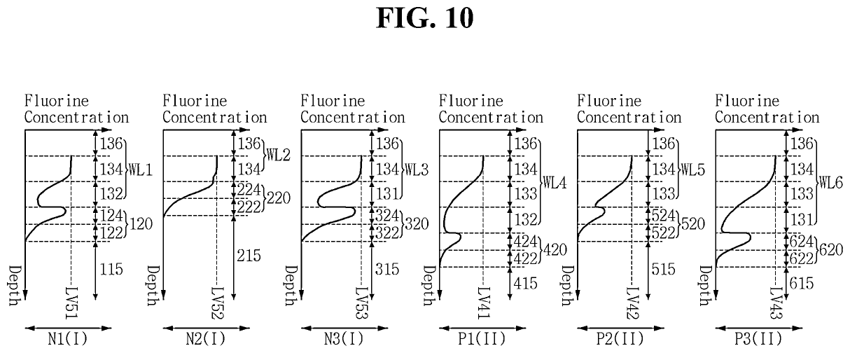

Each of the first to sixth gate structures GS1 to GS6 may contain fluorine (F). For example, at least a portion of each of the first to sixth gate structures GS1 to GS6 may be doped with fluorine (F). This will be described in more detail later with reference to FIGS. 5 to 10.

The first to sixth gate structures GS1 to GS6 may include first to sixth gate dielectric films 120, 220, 320, 420, 520 and 620 and first to sixth gate electrodes 130, 230, 330, 430, 530 and 630, respectively.

The first to sixth gate dielectric films 120, 220, 320, 420, 520 and 620 may be stacked on the first to sixth active patterns AP1 to AP6, respectively. The first to sixth gate dielectric films 120, 220, 320, 420, 520 and 620 may be interposed between the first to sixth active patterns AP1 to AP6 and the first to sixth gate electrodes 130, 230, 330, 430, 530 and 630, respectively. The first to sixth gate dielectric films 120, 220, 320, 420, 520 and 620 may surround the peripheries of the first to sixth active patterns AP1 to AP6, respectively. The first to sixth gate dielectric films 120, 220, 320, 420, 520 and 620 may further extend along the upper surface of the field insulating film 105.

Each of the first to sixth gate dielectric films 120, 220, 320, 420, 520 and 620 may include at least one of, for example, silicon oxide, silicon oxynitride, silicon nitride, a high dielectric constant material having a dielectric constant greater than that of silicon oxide or their combination. The high dielectric constant material may include, for example, hafnium oxide (HfO₂), zirconium oxide (ZrO₂), lanthanum oxide (La₂O₃), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}) or their combination, but is not limited thereto.

In one or more embodiments, as shown in FIG. 4, the first to sixth gate dielectric films 120, 220, 320, 420, 520 and 620 may include first to sixth interfacial films 122, 222, 322, 422, 522 and 622 and first to sixth high dielectric films 124, 224, 324, 424, 524 and 624, respectively. The first to sixth interfacial films 122, 222, 322, 422, 522 and 622 and the first to sixth high dielectric films 124, 224, 324, 424, 524 and 624 may be sequentially stacked on the first to sixth active patterns AP1 to AP6, respectively.

The first to sixth interfacial films 122, 222, 322, 422, 522 and 622 may be interposed between the first to sixth active patterns AP1 to AP6 and the first to sixth high dielectric films 124, 224, 324, 424, 524 and 624, respectively. The first to sixth interfacial films 122, 222, 322, 422, 522 and 622 may extend to be conformal along the peripheries of the first to sixth active patterns AP1 to AP6, respectively. Each of the first to sixth interfacial films 122, 222, 322, 422, 522 and 622 may include at least one of, for example, silicon oxide, silicon oxynitride and silicon nitride.

In one or more embodiments, the first to sixth interfacial films 122, 222, 322, 422, 522 and 622 may include an oxide of a material included in the first to sixth active patterns AP1 to AP6, respectively. For example, when the first to sixth active patterns AP1 to AP6 are silicon (Si) patterns, the first to sixth interfacial films 122, 222, 322, 422, 522 and 622 may include a silicon oxide (SiO) film. The first to sixth interfacial films 122, 222, 322, 422, 522 and 622 may be formed by, for example, a chemical oxidation process, an ultraviolet (UV) oxidation process or a dual plasma oxidation process, but are not limited thereto.

The first to sixth high dielectric films 124, 224, 324, 424, 524 and 624 may be interposed between the first to sixth interfacial films 122, 222, 322, 422, 522 and 622 and the first to sixth gate electrodes 130, 230, 330, 430, 530 and 630, respectively. The first to sixth high dielectric films 124, 224, 324, 424, 524 and 624 may extend to be conformal along the peripheries of the first to sixth interfacial films 122, 222, 322, 422, 522 and 622, respectively. Each of the first to sixth high dielectric films 124, 224, 324, 424, 524 and 624 may include a high dielectric material having a dielectric constant greater than that of silicon oxide. For example, each of the first to sixth high dielectric films 124, 224, 324, 424, 524 and 624 may include a hafnium oxide film (HfO).

The semiconductor device according to one or more embodiments may include a negative capacitance (NC) FET based on a negative capacitor. For example, each of the first to sixth gate dielectric films 120, 220, 320, 420, 520 and 620 may include a ferroelectric material film having ferroelectric characteristics and a paraelectric material film having paraelectric characteristics.

The ferroelectric material film may have a negative capacitance, and the paraelectric material film may have a positive capacitance. For example, when two or more capacitors are connected in series and the capacitance of each capacitor has a positive value, the total capacitance is more reduced than the capacitance of each individual capacitor. On the other hand, when at least one of capacitances of two or more capacitors connected in series has a negative value, the total capacitance may have a positive value and may be greater than an absolute value of each individual capacitance.

When the ferroelectric material film having a negative capacitance and the paraelectric material film having a positive capacitance are connected in series, the total capacitance value of the ferroelectric material film and the paraelectric material film, which are connected in series, may be increased. Based on the total capacitance value that is increased, a transistor having the ferroelectric material film may have a subthreshold swing (SS) less than 60 mV/decade at a room temperature.

The ferroelectric material film may have ferroelectric characteristics. The ferroelectric material film may include at least one of, for example, hafnium oxide, hafnium zirconium oxide, barium strontium titanium oxide, barium titanium oxide and lead zirconium titanium oxide. In this case, for example, the hafnium zirconium oxide may be a material doped with zirconium (Zr) in hafnium oxide. For another example, the hafnium zirconium oxide may be a compound of hafnium (Hf), zirconium (Zr) and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) and tin (Sn). A type of the dopant included in the ferroelectric material film may be varied depending on what the ferroelectric material the ferroelectric material film contains.

When the ferroelectric material film includes hafnium oxide, the dopant included in the ferroelectric material film may include at least one of gadolinium (Gd), silicon (Si), zirconium (Zr), aluminum (Al) and yttrium (Y).

When the dopant is aluminum (Al), the ferroelectric material film may include aluminum of 3 atomic % (at %) to 8 at %. In this case, a ratio of the dopant may be a ratio of aluminum to a sum of hafnium and aluminum.

When the dopant is silicon (Si), the ferroelectric material film may include silicon of 2 at % to 10 at %. When the dopant is yttrium (Y), the ferroelectric material film may include yttrium of 2 at % to 10 at %. When the dopant is gadolinium (Gd), the ferroelectric material film may include gadolinium of 1 at % to 7 at %. When the dopant is zirconium (Zr), the ferroelectric material film may include zirconium of 50 at % to 80 at %.

The paraelectric material film may have paraelectric characteristics. The paraelectric material film may include at least one of, for example, silicon oxide and metal oxide having a high dielectric constant. The metal oxide included in the paraelectric material film may include at least one of, for example, hafnium oxide, zirconium oxide and aluminum oxide, but is not limited thereto.

The ferroelectric material film and the paraelectric material film may include the same material. Although the ferroelectric material film has ferroelectric characteristics, the paraelectric material film may not have ferroelectric characteristics. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness having ferroelectric characteristics. The thickness of the ferroelectric material film may be, for example, 0.5 nm to 10 nm, but is not limited thereto. Since a threshold thickness indicating ferroelectric characteristics may be varied depending on each ferroelectric material, the thickness of the ferroelectric material film may be varied depending on the ferroelectric material.

For example, each of the first to sixth gate dielectric films 120, 220, 320, 420, 520 and 620 may include one ferroelectric material film. For another example, each of the first to sixth gate dielectric films 120, 220, 320, 420, 520 and 620 may include a plurality of ferroelectric material films spaced apart from each other. Each of the first to sixth gate dielectric films 120, 220, 320, 420, 520 and 620 may have a stacked layer structure in which a plurality of ferroelectric material films and a plurality of paraelectric material films are alternately stacked.

The first to sixth gate electrodes 130, 230, 330, 430, 530 and 630 may be respectively stacked on the first to sixth gate dielectric films 120, 220, 320, 420, 520 and 620. The first to sixth gate electrodes 130, 230, 330, 430, 530, 530 and 630 may respectively surround the peripheries of the first to sixth gate dielectric films 120, 220, 320, 420, 520 and 620.

The first to sixth gate electrodes 130, 230, 330, 430, 530 and 630 may respectively include first to sixth work function control films WL1 to WL6, first to sixth capping films BL1 to BL6 and first to sixth filling films FL1 to FL6. The first to sixth work function control films WL1 to WL6, the first to sixth capping films BL1 to BL6 and the first to sixth filling films FL1 to FL6 may be sequentially stacked on the first to sixth gate dielectric films 120, 220, 320, 420, 520 and 620, respectively.

The first to sixth work function control films WL1 to WL6 may extend to be conformal along the peripheries of the first to sixth high dielectric films 124, 224, 324, 424, 524 and 624, respectively. The first to sixth work function control films WL1 to WL6 may control effective work functions of the first to sixth gate electrodes 130, 230, 330, 430, 530 and 630, respectively.

In one or more embodiments, a thickness Tp1 of the fourth work function control film WL4 may be greater than a thickness Tn1 of the first work function control film WL1, a thickness Tp2 of the fifth work function control film WL5 may be greater than a thickness Tn2 of the second work function control film WL2, and a thickness Tp3 of the sixth work function control film WL6 may be greater than a thickness Tn3 of the third work function control film WL3.

In one or more embodiments, as shown in FIG. 4, a first work function insulating film 131, a second work function insulating film 132, a first work function conductive film 133, a second work function conductive film 134 and a third work function conductive film 136 may be provided.

In detail, the first work function control film WL1 may include the second work function insulating film 132, the second work function conductive film 134 and the third work function conductive film 136, which may be sequentially stacked on the first high dielectric film 124. The second work function control film WL2 may include the second work function conductive film 134 and the third work function conductive film 136, which may be sequentially stacked on the second high dielectric film 224. The third work function control film WL3 may include the first work function insulating film 131, the second work function conductive film 134 and the third work function conductive film 136, which may be sequentially stacked on the third high dielectric film 324.

Also, the fourth work function control film WL4 may include the second work function insulating film 132, the first work function conductive film 133, the second work function conductive film 134 and the third work function conductive film 136, which may be sequentially stacked on the fourth high dielectric film 424. The fifth work function control film WL5 may include the first work function conductive film 133, the second work function conductive film 134 and the third work function conductive film 136, which may be sequentially stacked on the fifth high dielectric film 524. The sixth work function control film WL6 may include the first work function insulating film 131, the first work function conductive film 133, the second work function conductive film 134 and the third work function conductive film 136, which may be sequentially stacked on the sixth high dielectric film 624.

Each of the first work function insulating film 131 and the second work function insulating film 132 may include an oxide of a dipole element capable of controlling effective work functions of the first to sixth gate electrodes 130, 230, 330, 430, 530 and 630. The dipole element may include at least one of, for example, La, Al, Zr, Nd, Eu, Dy, Ho, Yb or their combination, but is not limited thereto.

In one or more embodiments, the first work function insulating film 131 may increase the effective work functions of the first to sixth gate electrodes 130, 230, 330, 430, 530 and 630, and the second work function insulating film 132 may lower the effective work functions of the first to sixth gate electrodes 130, 230, 330, 430, 530 and 630. For example, the first work function insulating film 131 may include an aluminum oxide film (AlO), and the second work function insulating film 132 may include a lanthanum oxide film (LaO).

Each of the first work function conductive film 133, the second work function conductive film 134 and the third work function conductive film 136 may include, for example, metal nitride, metal oxynitride, metal oxycarbide, or metal oxynitride carbide, which is capable of controlling the effective work functions of the first to sixth gate electrodes 130, 230, 430, 530 and 630. The metal may include, but is not limited to, Ti, Ta, Nb, Al, W, Mo or their combination.

In one or more embodiments, the first work function conductive film 133 may be a p-type work function metal film having a relatively high work function. For example, the first work function conductive film 133 may include metal aluminum nitride or metal silicon nitride. For example, the first work function conductive film 133 may include a titanium aluminum nitride film (TiAlN).

In one or more embodiments, the second work function conductive film 134 may be a capping metal film disposed below the third work function conductive film 136. For example, the second work function conductive film 134 may include metal nitride. For example, the second work function conductive film 134 may include a titanium nitride film (TiN).

In one or more embodiments, the third work function conductive film 136 may be an n-type work function metal film having a relatively low work function. For example, the third work function conductive film 136 may include metal aluminum carbide or metal silicon carbide. For example, the third work function conductive film 136 may include a titanium aluminum carbide film (TiAlC).

In one or more embodiments, the third work function conductive film 136 may not contain fluorine (F).

The first to sixth capping films BL1 to BL6 may extend to be conformal along the peripheries of the first to sixth work function control films WL1 to WL6, respectively. The first to sixth capping films BL1 to BL6 may be capping metal films interposed between the first to sixth work function control films WL1 to WL6 and the first to sixth filling films FL1 to FL6, respectively. For example, each of the first to sixth capping films BL1 to BL6 may include metal nitride. For example, each of the first to sixth capping films BL1 to BL6 may include a titanium nitride film (TiN).

In one or more embodiments, each of the first to sixth capping layers BL1 to BL6 may not contain fluorine (F).

Each of the first to sixth filling films FL1 to FL6 may fill a space on the first to sixth capping films BL1 to BL6, respectively. The first to sixth filling films FL1 to FL6 may include a low resistance metal having an electrical resistance lower than that of the first to sixth work function control films WL1 to WL6, respectively. The low resistance metal may include at least one of, for example, Al, W, Ti, Ta or their combination, but is not limited thereto.

In one or more embodiments, each of the first to sixth filling films FL1 to FL6 may not contain fluorine (F).

The first to sixth gate spacers 140, 240, 340, 440, 540 and 640 may extend alongside surfaces of the first to sixth gate structures GS1 to GS6, respectively. In one or more embodiments, portions of the first to sixth gate dielectric films 120, 220, 320, 420, 520 and 620 may be interposed between the first to sixth gate electrodes 130, 230, 430, 530 and 630 and the first to sixth gate spacers 140, 240, 340, 440, 540 and 640, respectively. For example, the first to sixth gate dielectric films 120, 220, 320, 420, 520 and 620 may be further extended along at least portions of inner side surfaces of the first to sixth gate spacers 140, 240, 340, 440, 540 and 640, respectively.

Each of the first to sixth gate spacers 140, 240, 340, 440, 540 and 640 may include an insulating material, such as silicon nitride, silicon oxynitride, silicon oxycarbide, silicon boron nitride, silicon boron carbonitride, silicon oxycarbonitride or their combination, but is not limited thereto.

The first to sixth gate capping films 150, 250, 350, 450, 550 and 650 may extend along the upper surfaces of the first to sixth gate structures GS1 to GS6, respectively. In one or more embodiments, each of the upper surfaces of the first to sixth gate structures GS1 to GS6 may include a concave surface that is concave upward, and the first to sixth gate capping films 150, 250, 350, 450, 550 and 650 may be formed on the concave surfaces, respectively. Although the first to sixth gate capping films 150, 250, 350, 450, 550 and 650 are shown as only covering the upper surfaces of the first to sixth gate spacers 140, 240, 340, 440, 540 and 640, respectively, this is only an example.

Each of the first to sixth gate capping films 150, 250, 350, 450, 550 and 650 may include an insulating material, such as silicon nitride, silicon oxynitride, silicon oxycarbide, silicon boron nitride, silicon boron carbonitride, silicon oxycarbonitride or their combination, but is not limited thereto.

The first to sixth source/drain patterns 160, 260, 360, 460, 560 and 660 may be formed on at least one side surface (e.g., both side surfaces) of the first to sixth gate structures GS1 to GS6, respectively. The first to sixth source/drain patterns 160, 260, 360, 460, 560 and 660 may be connected to the first to sixth active patterns AP1 to AP6, respectively. For example, the first to sixth bridge patterns 115, 215, 315, 415, 515 and 615 may be connected to the first to sixth source/drain patterns 160, 260, 360, 460, 560 and 660, respectively, by passing through the first to sixth gate structures GS1 to GS6 and the first to sixth gate spacers 140, 240, 340, 440, 540 and 640. The first to sixth source/drain patterns 160, 260, 360, 460, 560 and 660 may be separated from the first to sixth gate electrodes 130, 230, 330, 430, 530 and 630, respectively, by the first to sixth gate dielectric films 120, 220, 320, 420, 520 and 620 and/or the first to sixth gate spacers 140, 240, 340, 440, 540 and 640.

In one or more embodiments, each of the first to sixth source/drain patterns 160, 260, 360, 460, 560 and 660 may include an epitaxial layer. For example, the first to sixth source/drain patterns 160, 260, 360, 460, 560 and 660 may be formed by an epitaxial growth method from the substrate 100 and/or the first to sixth active patterns AP1 to AP6, respectively. The first to sixth source/drain patterns 160, 260, 360, 460, 560 and 660 may be provided as source/drain regions of the first to sixth transistors TR1 to TR6, respectively.

Each of the first to third source/drain patterns 160, 260 and 360 formed on the N-type region I may include an n-type impurity or an impurity for preventing diffusion of the n-type impurity. For example, each of the first to third source/drain patterns 160, 260 and 360 may include at least one of P, Sb, As or their combination.

In one or more embodiments, the first to third source/drain patterns 160, 260 and 360 may further include a tensile stress material. For example, when the first to third active patterns AP1 to AP3 are silicon (Si) patterns, the first to third source/drain patterns 160, 260 and 360 may include a material (e.g., silicon carbide (SiC) having a lattice constant smaller than that of silicon (Si). The tensile stress material may improve carrier mobility of a channel region by applying a tensile stress to the first to third active patterns AP1 to AP3.

Each of the fourth to sixth source/drain patterns 460, 560 and 660 formed on the P-type region II may include a p-type impurity or an impurity for preventing diffusion of the p-type impurity. For example, each of the fourth to sixth source/drain patterns 460, 560 and 660 may include at least one of B, In, Ga, Al or their combination.

In one or more embodiments, the fourth to sixth source/drain patterns 460, 560 and 660 may further include a compression stress material. For example, when the fourth to sixth active patterns AP4 to AP6 are silicon (Si) patterns, the fourth to sixth source/drain patterns 460, 560 and 660 may include a material (e.g., silicon germanium (SiGe)) having a lattice constant greater than that of silicon (Si). The compression stress material may improve carrier mobility of a channel region by applying a compression stress to the fourth to sixth active patterns AP4 to AP6.

The interlayer insulating film 180 may be formed on the substrate 100 and the field insulating film 105. The interlayer insulating film 180 may be formed to fill a space on the first to sixth source/drain patterns 160, 260, 360, 460, 560 and 660. Although the interlayer insulating film 180 is only shown as exposing upper surfaces of the first to sixth gate capping films 150, 250, 350, 450, 550 and 650, this is only an example.

The interlayer insulating film 180 may include at least one of, for example, silicon oxide, silicon nitride, silicon oxynitride, silicon oxycarbide, silicon boron nitride, silicon boron carbonitride, silicon oxycarbonitride, a low dielectric constant material having a dielectric constant smaller than that of silicon oxide, and combinations thereof, but is not limited thereto. The low dielectric constant material may include Flowable Oxide (FOX), Torene SilaZene (TOSZ), Undoped Silica Glass (USG), Borosilica Glass (BSG), PhosphoSilica Glass (PSG), BoroPhosphoSilica Glass (BPSG), Plasma Enhanced Tetra Ethyl Ortho Silicate (PETEOS), Fluoride Silicate Glass (FSG), Carbon Doped silicon Oxide (CDO), Xerogel, Aerogel, Amorphous Fluorinated Carbon, Organo Silicate Glass (OSG), Parylene, bis-benzocyclobutenes (BCB), SiLK, polyimide, porous polymeric material or their combination, but is not limited thereto.

FIGS. 5 to 10 are graphs illustrating a fluorine (F) concentration of a semiconductor device according to one or more embodiments. For convenience of description, redundant portions of those described above with reference to FIGS. 1 to 4 may be briefly described or omitted.

Referring to FIGS. 1 to 5, in the semiconductor device according to one or more embodiments, each of the first to sixth gate dielectric films 120, 220, 320, 420, 520 and 620, the first work function insulating film 131, the second work function insulating film 132 and the first work function conductive film 133 may include fluorine (F).

Each of the second work function conductive film 134 and the third work function conductive film 136 may not contain fluorine (F). For example, the second work function conductive film 134 and the third work function conductive film 136 may be formed by being stacked on the first to sixth gate dielectric films 120, 220, 320, 420, 520 and 620, the first work function insulating film 131, the second work function insulating film 132 and the first work function conductive film 133 after the first to sixth gate dielectric films 120, 220, 320, 420, 520 and 620, the first work function insulating film 131, the second work function insulating film 132 and the first work function conductive film 133 are doped with fluorine (F).

Fluorine (F) doped into the first to sixth gate dielectric films 120, 220, 320, 420, 520 and 620 may reduce a leakage current and improve reliability by repairing oxygen vacancy in the first to sixth high dielectric films 124, 224, 324, 424, 524 and 624. In addition, fluorine (F) doped into the first to sixth work function control films WL1 to WL6 may control threshold voltages of the first to sixth transistors TR1 to TR6 by increasing the effective work function. Therefore, a semiconductor device with improved performance and reliability may be provided.

In one or more embodiments, a fluorine (F) concentration of each layer containing fluorine (F) may be reduced based on a distance of each layer respectively from the first to sixth active patterns AP1 to AP6. For example, the fluorine (F) concentration of the first work function conductive film 133 may be gradually reduced as the distance increases from a boundary surface between the first work function conductive film 133 and the second work function conductive film 134. On the N-type region I, the fluorine (F) concentration of the first work function insulating film 131 and the fluorine (F) concentration of the second work function insulating film 132 may be gradually reduced as the distance increases from the second work function conductive film 134. On the P-type region II, the fluorine (F) concentration of the first work function insulating film 131 and the fluorine (F) concentration of the second work function insulating film 132 may be gradually reduced as the distance increases from the first work function conductive film 133. The fluorine (F) concentrations of the first to sixth gate dielectric films 120, 220, 320, 420, 520 and 620 may be gradually reduced and then may be zero (0) as the distance decreases to the first to sixth active patterns AP1 to AP6, respectively.

In one or more embodiments, an average fluorine concentration of the first work function insulating film 131 and an average fluorine concentration of the second work function insulating film 132 may be smaller than an average fluorine concentration of the first work function conductive film 133. For example, on the fourth region P1, the fluorine (F) concentration may be gradually reduced from the boundary surface between the first work function conductive film 133 and the second work function conductive film 134 toward a boundary surface between the fourth high dielectric film 424 and the second work function insulating film 132. Also, for example, on the sixth region P3, the fluorine (F) concentration may be gradually reduced from the boundary surface between the first work function conductive film 133 and the second work function conductive film 134 toward a boundary surface between the sixth high dielectric film 624 and the first work function insulating film 131.

In one or more embodiments, a maximum fluorine concentration of the first work function conductive film 133 may be about 5 at % to about 10 at % or about 6 at % to about 7 at %.

In one or more embodiments, the average fluorine concentration of the first work function insulating film 131 and the average fluorine concentration of the second work function insulating film 132 may be smaller than an average fluorine concentration of the first to sixth high dielectric films 124, 224, 324, 424, 524 and 624. For example, on the first region N1 and the fourth region P1, the fluorine (F) concentration may be increased toward the first and fourth high dielectric films 124 and 424 in the vicinity of a boundary surface between the first and fourth high dielectric films 124 and 424 and the second work function insulating film 132. Also, for example, on the third region N3 and the sixth region P3, the fluorine (F) concentration may be increased toward the third and sixth high dielectric films 324 and 624 in the vicinity of a boundary surface between the third and sixth high dielectric films 324 and 624 and the first work function insulating film 131.

An average fluorine concentration of the fourth to sixth gate dielectric films 420, 520 and 620 on the P-type region II may be smaller than or equal to an average fluorine concentration of the first to third gate dielectric films 120, 220 and 320 on the N-type region I. In one or more embodiments, the average fluorine concentration of the fourth to sixth high dielectric films 424, 524 and 624 may be smaller than the average fluorine concentration of the first to third high dielectric films 124, 224 and 324 on the N-type region I. For example, a maximum fluorine concentration LV21 of the fourth high dielectric film 424 may be smaller than a maximum fluorine concentration LV11 of the first high dielectric film 124, a maximum fluorine concentration LV22 of the fifth high dielectric film 524 may be smaller than a maximum fluorine concentration LV12 of the second high dielectric film 224, and a maximum fluorine concentration LV23 of the sixth high dielectric film 624 may be smaller than a maximum fluorine concentration LV13 of the third high dielectric film 324. This may be due to additional arrangement of the first work function conductive film 133 on the P-type region II compared with the N-type region I. For example, the TiAlN film of the first work function conductive film 133 may have a relatively low fluorine transmittance as it has an amorphous structure.

In one or more embodiments, the maximum fluorine concentrations LV11 to LV13 of the first to third high dielectric films 124, 224 and 324 may be about 5 at % to 10 at %, respectively, and the maximum fluorine concentrations LV21 to LV23 of the fourth to sixth high dielectric films 424, 524 and 624 may be smaller than or equal to the maximum fluorine concentrations LV11 to LV13 of the first to third high dielectric films 124, 224 and 324.

In one or more embodiments, the average fluorine concentration of the first work function insulating film 131 on the P-type region II may be smaller than the average fluorine concentration of the first work function insulating film 131 on the N-type region I. In one or more embodiments, the average fluorine concentration of the second work function insulating film 132 on the P-type region II may be smaller than the average fluorine concentration of the second work function insulating film 132 on the N-type region I.

Referring to FIGS. 1 to 4 and 6, in the semiconductor device according to one or more embodiments, the fourth to sixth gate dielectric films 420, 520 and 620 on the P-type region II, the first work function insulating film 131 on the P-type region II and the second work function insulating film 132 on the P-type region II may not contain fluorine (F). For convenience of description, redundant portions of those described above with reference to FIG. 5 may be briefly described or omitted.

For example, on the P-type region II, the fluorine (F) concentration of the first work function conductive film 133 may be gradually reduced and then may be zero (0) as the distance increases from the boundary surface between the first work function conductive film 133 and the second work function conductive film 134. Therefore, unlike the first to third high dielectric films 124, 224 and 324 on the N-type region I, which contain fluorine (F), the fourth to sixth high dielectric films 424, 524 and 624 on the P-type region II may not contain fluorine (F).

Referring to FIGS. 1 to 4 and 7, in the semiconductor device according to one or more embodiments, the second work function conductive film 134 may contain fluorine (F). For convenience of description, redundant portions of those described above with reference to FIG. 5 will be briefly described or omitted.

The third work function conductive film 136 may not contain fluorine (F). For example, the third work function conductive film 136 may be formed by being stacked on the second work function conductive film 134 after the second work function conductive film 134 is doped with fluorine (F).

In one or more embodiments, the fluorine (F) concentration of the second work function conductive film 134 may be gradually reduced as the distance increases from a boundary surface between the second work function conductive film 134 and the third work function conductive film 136. In one or more embodiments, the average fluorine concentration of the first work function conductive film 133 may be smaller than an average fluorine concentration of the second work function conductive film 134.

In one or more embodiments, the average fluorine concentration of the fourth to sixth high dielectric films 424, 524 and 624 may be smaller than the average fluorine concentration of the first to third high dielectric films 124, 224 and 324 on the N-type region I. This may be due to additional arrangement of the first work function conductive film 133 on the P-type region II compared with the N-type region I. For example, unlike the TiN film of the second work function conductive film 134, which has a columnar structure, the TiAlN film of the first work function conductive film 133 may have a relatively low fluorine transmittance because it has an amorphous structure.

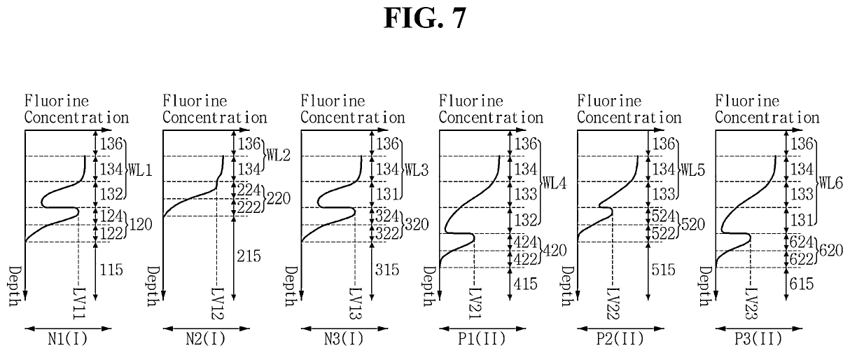

Referring to FIGS. 1 to 4 and 8, in the semiconductor device according to one or more embodiments, the fourth to sixth gate dielectric films 420, 520 and 620 on the P-type region II, the first work function insulating film 131 on the P-type region II and the second work function insulating film 132 on the P-type region II may not contain fluorine (F). For convenience of description, redundant portions of those described above with reference to FIG. 7 may be briefly described or omitted.

For example, on the P-type region II, the fluorine (F) concentration of the first work function conductive film 133 may be gradually reduced and then may be zero (0) as the distance increases from the boundary surface between the second work function conductive film 134 and the third work function conductive film 136. Therefore, unlike the first to third high dielectric films 124, 224 and 324 on the N-type region I, which contain fluorine (F), the fourth to sixth high dielectric films 424, 524 and 624 on the P-type region II may not contain fluorine (F).

Referring to FIGS. 1 to 4 and 9, in the semiconductor device according to one or more embodiments, the first work function conductive film 133 on the fourth to sixth regions P1 to P3 may have different fluorine (F) concentrations. For convenience of description, redundant portions of those described above with reference to FIG. 5 may be briefly described or omitted.

On the P-type region II, as the fluorine (F) concentration of the first work function conductive film 133 is increased, a work function may be increased so that a threshold voltage may be reduced. For example, a maximum fluorine concentration LV32 of the first work function conductive film 133 on the fifth region P2 may be greater than a maximum fluorine concentration LV31 of the first work function conductive film 133 on the fourth region P1, and a maximum fluorine concentration LV33 of the first work function conductive film 133 on the sixth region P3 may be greater than the maximum fluorine concentration LV32 of the first work function conductive film 133 on the fifth region P2.

Referring to FIGS. 1 to 4 and 10, in the semiconductor device according to one or more embodiments, the second work function conductive film 134 on the fourth to sixth regions P1 to P3 may have different fluorine (F) concentrations. For convenience of description, redundant portions of those described above with reference to FIG. 7 may be briefly described or omitted.

On the P-type region II, as the fluorine (F) concentration of the second work function conductive film 134 is increased, the work function may be increased so that the threshold voltage may be reduced. For example, a maximum fluorine concentration LV42 of the second work function conductive film 134 on the fifth region P2 may be greater than a maximum fluorine concentration LV41 of the second work function conductive film 134 on the fourth region P1, and a maximum fluorine concentration LV43 of the second work function conductive film 134 on the sixth region P3 may be greater than the maximum fluorine concentration LV42 of the second work function conductive film 134 on the fifth region P2.

In one or more embodiments, the second work function conductive film 134 on the first to third regions N1 to N3 may have different fluorine (F) concentrations. On the N-type region I, as the fluorine (F) concentration of the second work function conductive film 134 is increased, the work function may be increased so that the threshold voltage may be increased. For example, a maximum fluorine concentration LV52 of the second work function conductive film 134 on the second region N2 may be greater than a maximum fluorine concentration LV51 of the second work function conductive film 134 on the first region N1, and a maximum fluorine concentration LV53 of the second work function conductive film 134 on the third region N3 may be greater than the maximum fluorine concentration LV52 of the second work function conductive film 134 on the second region N2.

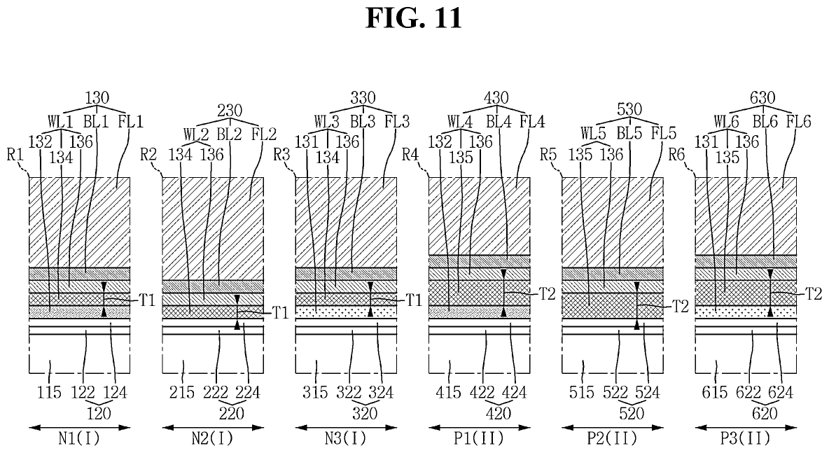

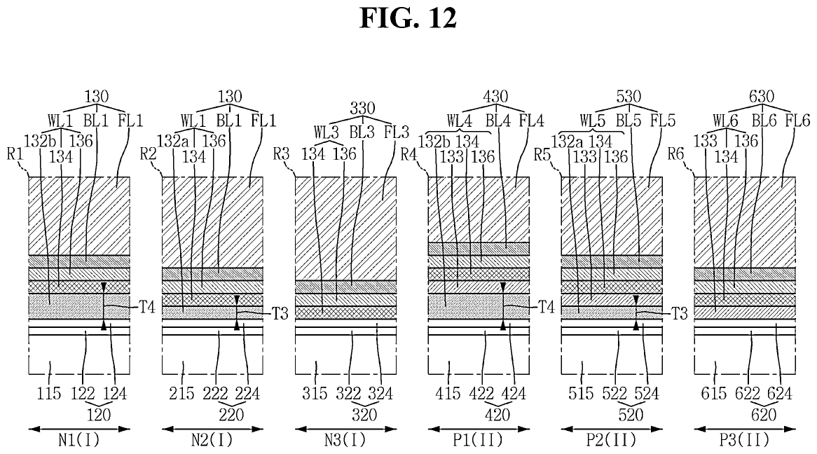

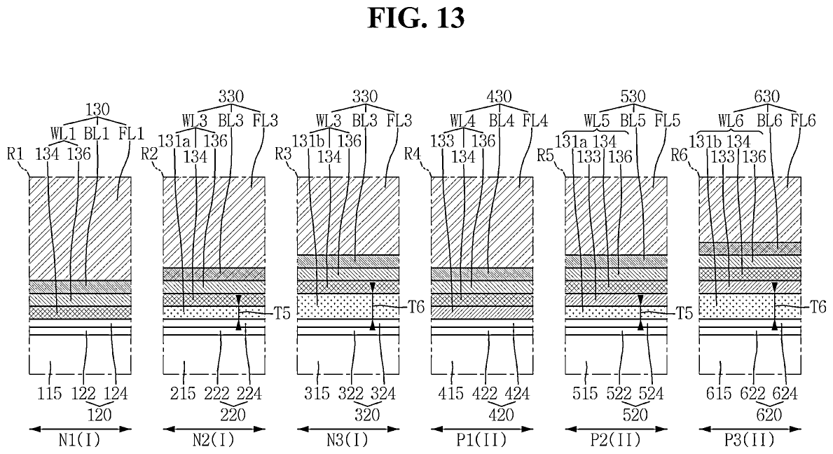

FIGS. 11 to 13 are enlarged views illustrating further examples of a region R1, a region R2, a region R3, a region R4, a region R5 and a region R6 of FIGS. 2A and 2B, according to one or more embodiments. For convenience of description, redundant portions of those described above with reference to FIGS. 1 to 10 may be briefly described or omitted.

Referring to FIGS. 1 to 3B and 11, in the semiconductor device according to one or more embodiments, each of the fourth to sixth work function control films WL4 to WL6 may include a fourth work function conductive film 135.

On the P-type region II, the fourth work function conductive film 135 may be formed below the third work function conductive film 136. The fourth work function conductive film 135 may be formed by replacing the first work function conductive film 133 and the second work function conductive film 134 in the P-type region II of FIG. 4. That is, the fourth to sixth work function adjustment films WL4 to WL6 may not include the first work function conductive film 133 and the second work function conductive film 134 of FIG. 4.

In one or more embodiments, the fourth work function conductive film 135 may include the same material as that of the second work function conductive film 134. For example, each of the second work function conductive film 134 and the fourth work function conductive film 135 may include a titanium nitride film (TiN).

In one or more embodiments, a thickness T2 of the fourth work function conductive film 135 may be greater than a thickness T1 of the second work function conductive film 134. Therefore, effective work functions of the fourth to sixth work function control films WL4 to WL6 may be greater than effective work functions of the first to third work function control films WL1 to WL3.

Referring to FIGS. 1 to 3B and 12, in the semiconductor device according to one or more embodiments, the second work function control film WL2 and the fifth work function control film WL5 may include a third work function insulating film 132a, and the first work function control film WL1 and the fourth work function control film WL4 may include a fourth work function insulating film 132b.

On the N-type region I, the third work function insulating film 132a and the fourth work function insulating film 132b may be formed below the second work function conductive film 134. On the P-type region II, the third work function insulating film 132a and the fourth work function insulating film 132b may be formed below the first work function conductive film 133. The first work function control film WL1 and the fourth work function control film WL4 may not include the second work function insulating film 132 of FIG. 4, and the third work function control film WL3 and the sixth work function control film WL6 may not include the first work function insulating film 131 of FIG. 4.

In one or more embodiments, each of the third work function insulating film 132a and the fourth work function insulating film 132b may include an oxide of a dipole element capable of lowering effective work functions of the first to sixth gate electrodes 130, 230, 330, 430, 530 and 630. For example, each of the third work function insulating film 132a and the fourth work function insulating film 132b may include a lanthanum oxide film (LaO).

In one or more embodiments, a thickness T4 of the fourth work function insulating film 132b may be greater than a thickness T3 of the third work function insulating film 132a. Therefore, the effective work function of the first work function control film WL1 may be smaller than the effective work function of the second work function control film WL2, and the effective work function of the second work function control film WL2 may be smaller than the effective work function of the third work function control film WL3. Furthermore, the effective work function of the fourth work function control film WL4 may be smaller than the effective work function of the fifth work function control film WL5, and the effective work function of the fifth work function control film WL5 may be smaller than the effective work function of the sixth work function control film WL6.

Referring to FIGS. 1 to 3B and 13, in the semiconductor device according to one or more embodiments, the second work function control film WL2 and the fifth work function control film WL5 may include a fifth work function insulating film 131a, and the third work function control film WL3 and the sixth work function control film WL6 may include a sixth work function insulating film 131b.

On the N-type region I, the fifth work function insulating film 131a and the sixth work function insulating film 131b may be formed below the second work function conductive film 134. On the P-type region II, the fifth work function insulating film 131a and the sixth work function insulating film 131b may be formed below the first work function conductive film 133. The first work function control film WL1 and the fourth work function control film WL4 may not include the second work function insulating film 132 of FIG. 4, and the third work function control film WL3 and the sixth work function control film WL6 may not include the first work function insulating film 131 of FIG. 4.

In one or more embodiments, each of the fifth work function insulating film 131a and the sixth work function insulating film 131b may include an oxide of a dipole element capable of increasing the effective work functions of the first to sixth gate electrodes 130, 230, 330, 430, 530 and 630. For example, each of the fifth work function insulating film 131a and the sixth work function insulating film 131b may include an aluminum oxide film (AlO).

In one or more embodiments, a thickness T6 of the sixth work function insulating film 131b may be greater than a thickness T5 of the fifth work function insulating film 131a. Therefore, the effective work function of the third work function control film WL3 may be greater than the effective work function of the second work function control film WL2, and the effective work function of the second work function control film WL2 may be greater than the effective work function of the first work function control film WL1. Furthermore, the effective work function of the sixth work function control film WL6 may be greater than the effective work function of the fifth work function control film WL5, and the effective work function of the fifth work function control film WL5 may be greater than the effective work function of the fourth work function control film WL4.

Hereinafter, a method for fabricating a semiconductor device according to some example embodiments will be described with reference to FIGS. 1 to 30.

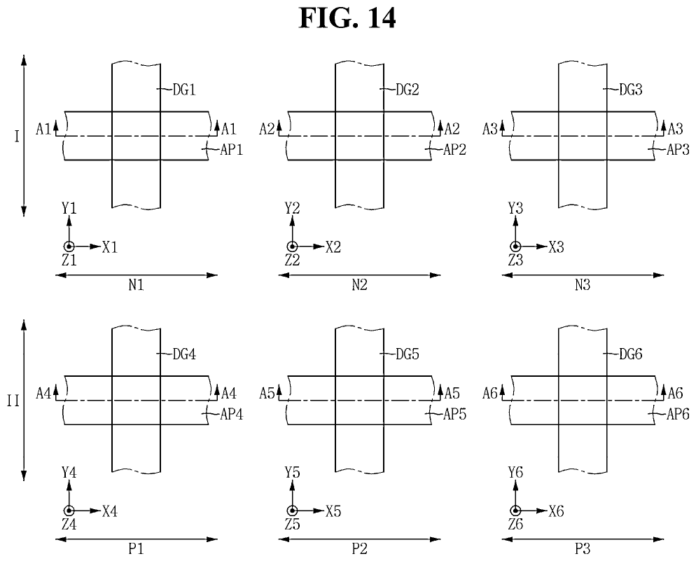

FIGS. 14 to 28 are diagrams illustrating operations of a method for fabricating a semiconductor device according to one or more embodiments. For convenience of description, redundant portions of those described above with reference to FIGS. 1 to 13 may be briefly described or omitted.

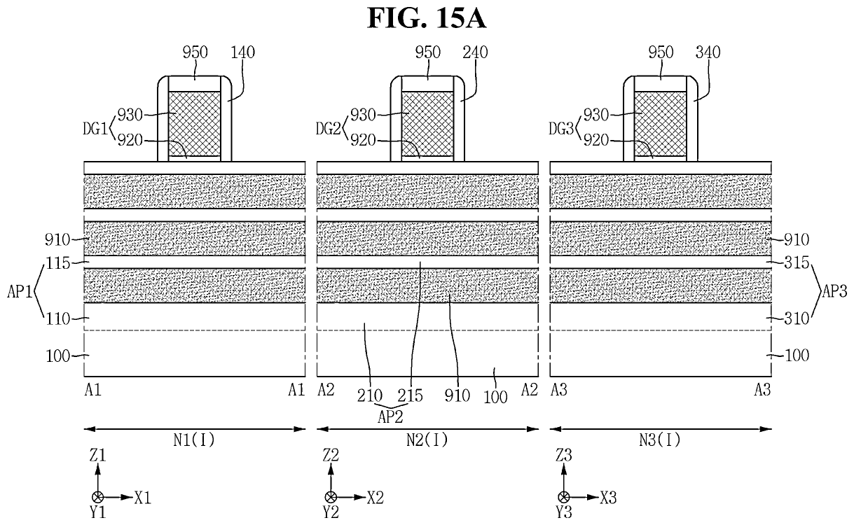

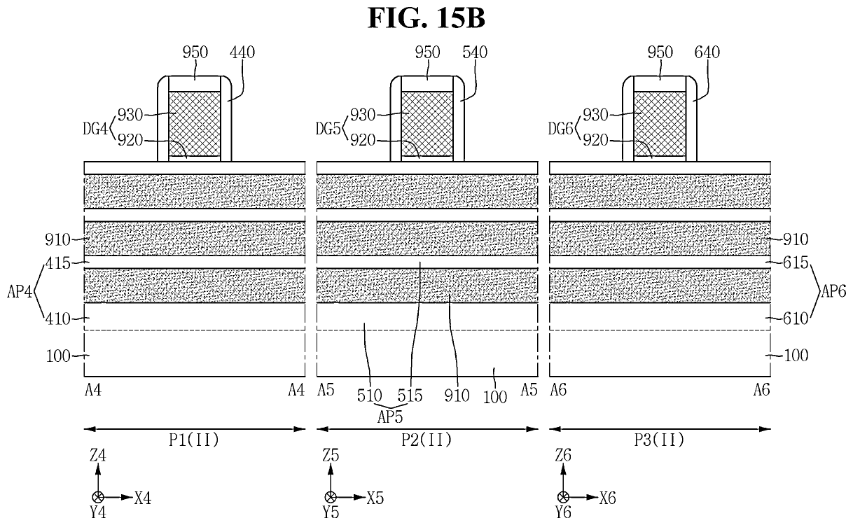

Referring to FIGS. 14, 15A and 15B, first to sixth active patterns AP1 to AP6, a sacrificial pattern 910, first to sixth dummy gate structures DG1 to DG6 and first to sixth gate spacers 140, 240, 340, 440, 540 and 640 may be formed on a substrate 100. For reference, FIG. 15A shows cross-sectional views taken along lines A1-A1, A2-A2 and A3-A3 of FIG. 14, and FIG. 15B shows cross-sectional views taken along lines A4-A4, A5-A5 and A6-A6 of FIG. 14.

For example, a first material film and a second material film, which are alternately stacked on the substrate 100, may be formed. Subsequently, a patterning process of patterning the first material film and the second material film may be performed. The first material film patterned in first to sixth regions N1, N2, N3, P1, P2 and P3 may form the sacrificial pattern 910, and the second material film patterned in the first to sixth regions N1, N2, N3, P1, P2 and P3 may form first to sixth bridge patterns 115, 215, 315, 415, 515 and 615, respectively, which are stacked alternately with the sacrificial pattern 910.

In one or more embodiments, in the process of patterning the first material film and the second material film, a portion of the substrate 100 may be etched so that first to sixth fin patterns 110, 210, 310, 410, 510 and 610 may be formed. As a result, the first to sixth active patterns AP1 to AP6, each of which includes first to sixth fin patterns 110, 210, 310, 410, 510 and 610 and at least one of first to sixth bridge pattern 115, 215, 315, 415, 515 and 615, may be formed.

The sacrificial pattern 910 may have etch selectivity with respect to the first to sixth active patterns AP1 to AP6. For example, each of the first to sixth active patterns AP1 to AP6 may be a silicon (Si) pattern, and the sacrificial pattern 910 may be a silicon germanium (SiGe) pattern.

Subsequently, the first to sixth dummy gate structures DG1 to DG6 may be formed on the first to sixth active patterns AP1 to AP6, respectively. The first to sixth dummy gate structures DG1 to DG6 may cross the first to sixth active patterns AP1 to AP6, respectively.

In one or more embodiments, each of the first to sixth dummy gate structures DG1 to DG6 may include a dummy gate dielectric film 920 and a dummy gate electrode 930. For example, a dielectric film and an electrode film, which are sequentially stacked on the first to sixth active patterns AP1 to AP6, may be formed. Subsequently, a mask pattern 950 may be formed on the electrode film. Subsequently, a patterning process of patterning the dielectric film and the electrode film using the mask pattern 950 as an etching mask may be performed. The patterned dielectric film may form the dummy gate dielectric film 920, and the patterned electrode film may form the dummy gate electrode 930.

The first to sixth dummy gate structures DG1 to DG6 may have etch selectivity with respect to the first to sixth active patterns AP1 to AP6. For example, each of the first to sixth dummy gate structures DG1 to DG6 may be a poly silicon (poly Si) pattern.

Subsequently, the first to sixth gate spacers 140, 240, 340, 440, 540 and 640 respectively extending alongside surfaces of the first to sixth dummy gate structures DG1-DG6 may be formed.

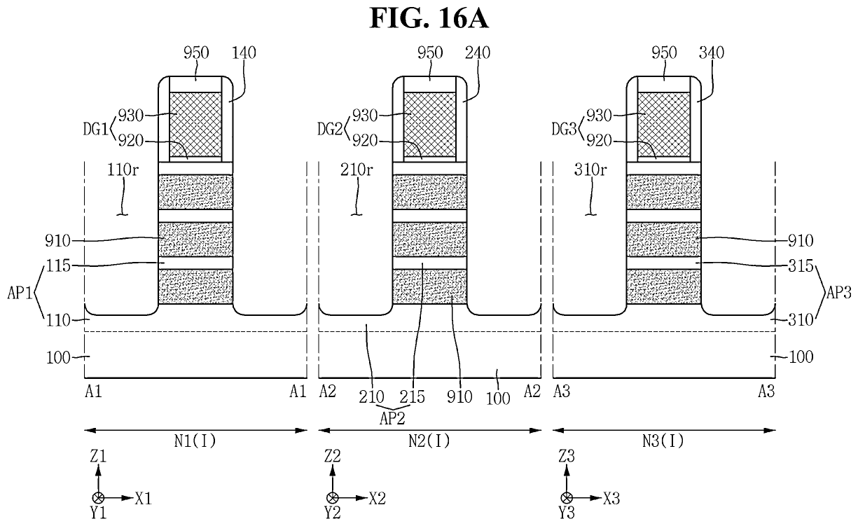

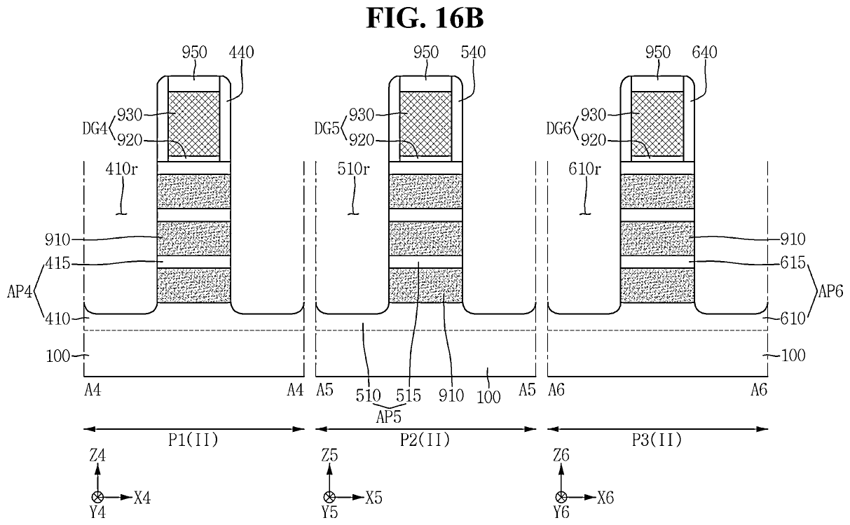

Referring to FIGS. 16A and 16B, a recess process for the first to sixth active patterns AP1 to AP6 and the sacrificial pattern 910 may be performed.

As the recess process is performed, a portion of the first to sixth active patterns AP1 to AP6 and a portion of the sacrificial pattern 910, which are disposed outside the first to sixth dummy gate structures DG1 to DG6, may be removed. As a result, first to sixth recesses 110r, 210r, 310r, 410r, 510r and 610r may be respectively formed in the first to sixth active patterns AP1 to AP6 and the sacrificial pattern 910.

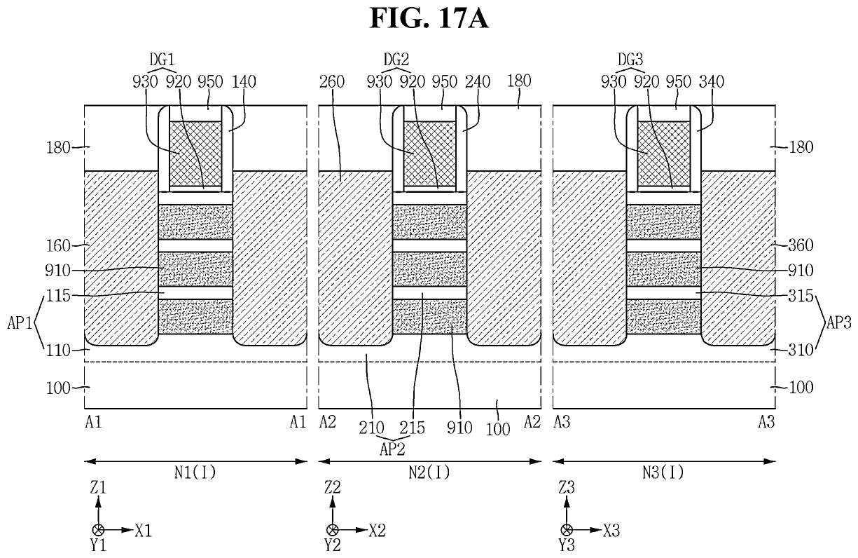

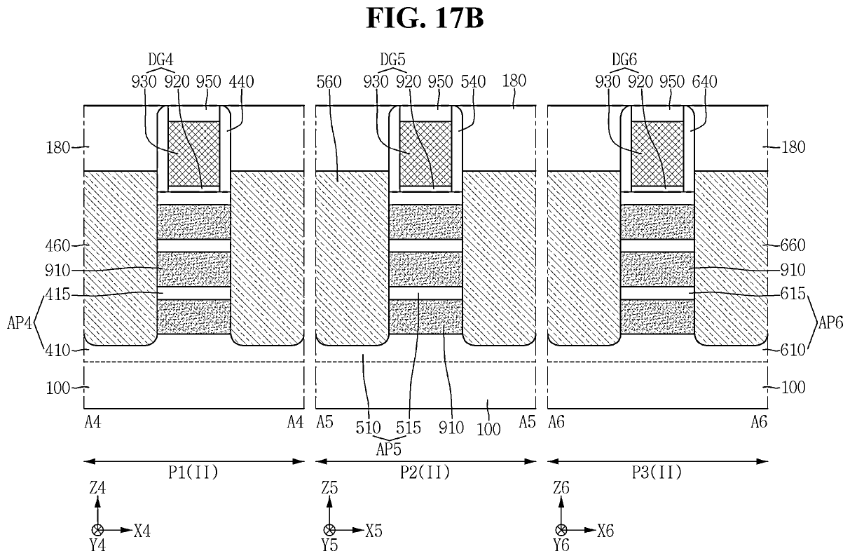

Referring to FIGS. 17A and 17B, first to sixth source/drain patterns 160, 260, 360, 460, 560 and 660 may be formed.

The first to third source/drain patterns 160, 260 and 360 may fill the first to third recesses 110r, 210r and 310r, respectively. For example, each of the first to third source/drain patterns 160, 260 and 360 may be formed by an epitaxial growth method that uses the first to third active patterns AP1 to AP3 as seed layers. As a result, the first to third source/drain patterns 160, 260 and 360 respectively connected to the first to third active patterns AP1 to AP3 may be formed.

The fourth to sixth source/drain patterns 460, 560 and 660 may fill the fourth to sixth recesses 410r, 510r and 610r, respectively. For example, each of the fourth to sixth source/drain patterns 460, 560 and 660 may be formed by an epitaxial growth method that uses the fourth to sixth active patterns AP4 to AP6 as seed layers. As a result, the fourth to sixth source/drain patterns 460, 560 and 660 respectively connected to the fourth to sixth active patterns AP4 to AP6 may be formed.

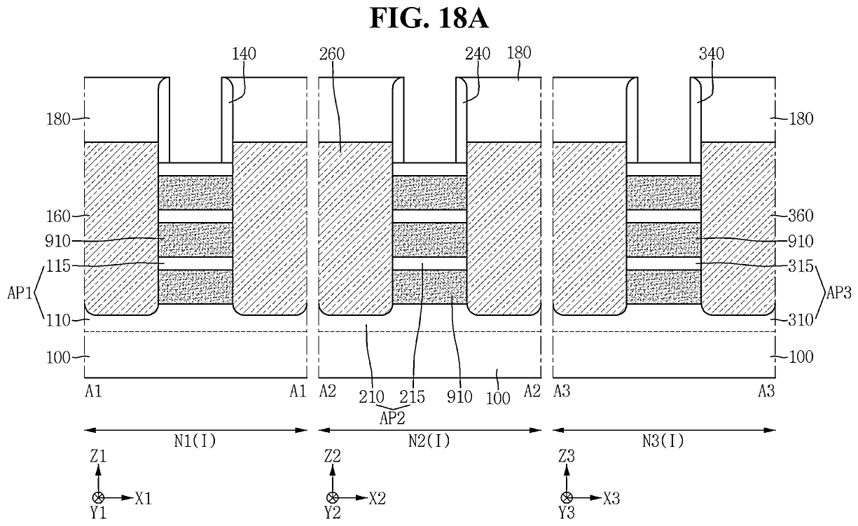

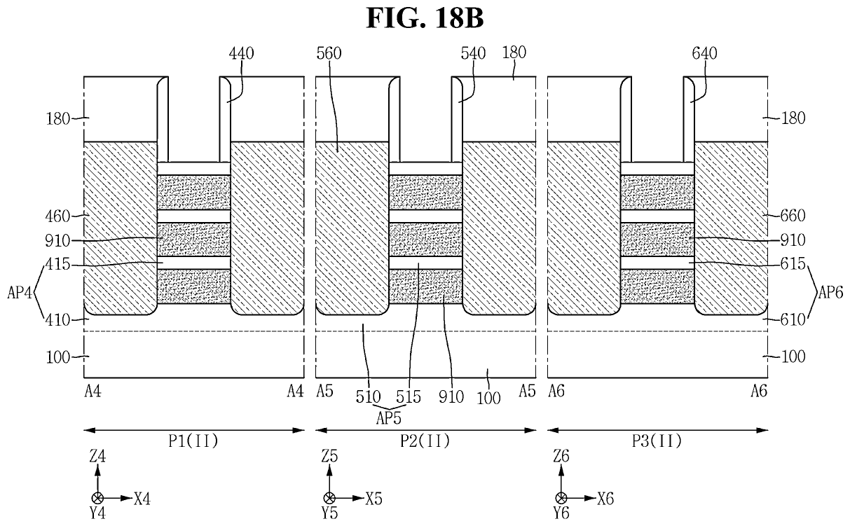

Referring to FIGS. 18A and 18B, the first to sixth dummy gate structures DG1 to DG6 may be removed.

The first to sixth dummy gate structures DG1 to DG6 may have etch selectivity with respect to the first to sixth active patterns AP1 to AP6, and thus may be selectively removed. As the first to sixth dummy gate structures DG1 to DG6 are removed, the first to sixth active patterns AP1 to AP6 and the sacrificial pattern 910, which are disposed inside the first to sixth gate spacers 140, 240, 340, 440, 540 and 640, may be exposed.

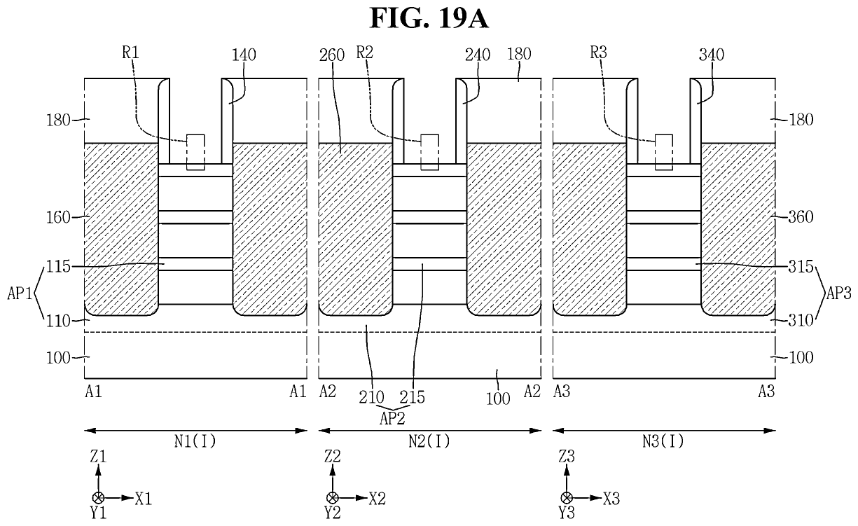

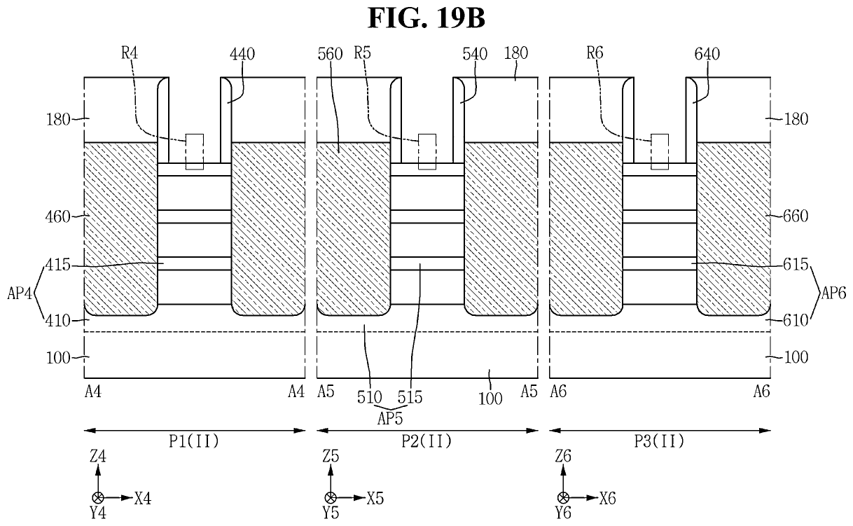

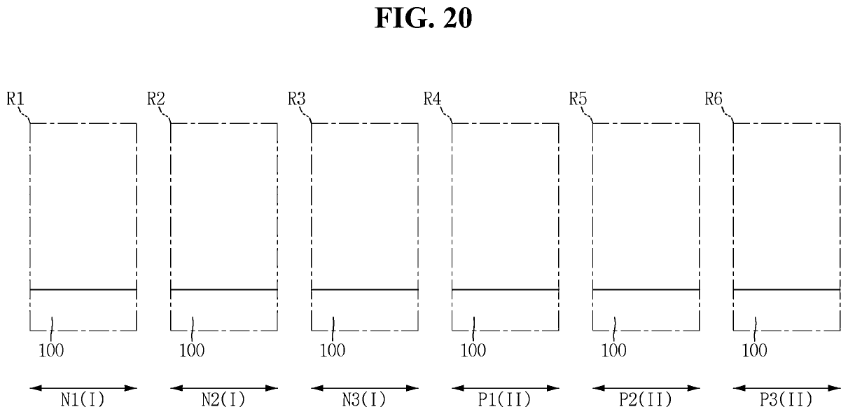

Referring to FIGS. 19A, 19B and 20, the sacrificial pattern 910 may be removed. For reference, FIG. 20 shows enlarged views illustrating a region R1, a region R2, a region R3, a region R4, a region R5 and a region R6 of FIGS. 19A and 19B.

The sacrificial pattern 910 may have etch selectivity with respect to the first to sixth active patterns AP1 to AP6, and thus may be selectively removed. As the sacrificial pattern 910 is removed, at least one of the first to sixth bridge patterns 115, 215, 315, 415, 515 and 615, which is spaced apart from the substrate 100, may be formed.

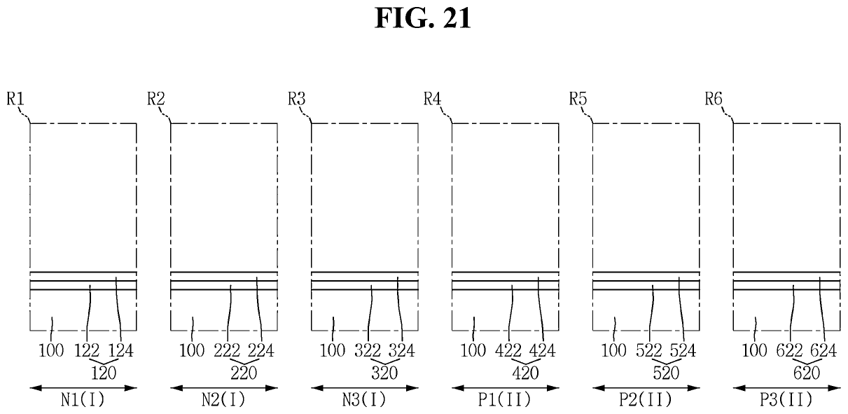

Referring to FIG. 21, first to sixth gate dielectric films 120, 220, 320, 420, 520 and 620 may be formed on the first to sixth active patterns AP1 to AP6, respectively.

For example, a chemical oxidation process, an ultraviolet (UV) oxidation process or a dual plasma oxidation process may be performed for the exposed first to sixth active patterns AP1 to AP6. As a result, first to sixth interfacial films 122, 222, 322, 422, 522 and 622 may be formed on the first to sixth active patterns AP1 to AP6, respectively.

Subsequently, first to sixth high dielectric films 124, 224, 324, 424, 524 and 624 may be formed on the first to sixth interfacial films 122, 222, 322, 422, 522 and 622, respectively. The first to sixth high dielectric films 124, 224, 324, 424, 524 and 624 may be formed by, for example, a chemical vapor deposition (CVD) method, an atomic layer deposition (ALD) or the like, but are not limited thereto. In one or more embodiments, the first to sixth interfacial films 122, 222, 322, 422, 522 and 622 may be formed at the same level (i.e., formed by the same fabricating process).

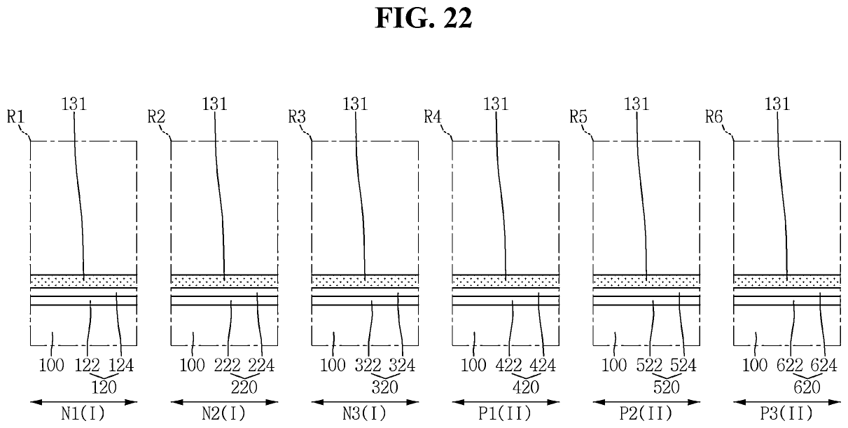

Referring to FIG. 22, a first work function insulating film 131 may be formed on the first to sixth gate dielectric films 120, 220, 320, 420, 520 and 620.

The first work function insulating film 131 may extend to be conformal along surfaces of the first to sixth gate dielectric films 120, 220, 320, 420, 520 and 620. In one or more embodiments, the first work function insulating film 131 may include an oxide of a dipole element capable of increasing an effective work function. For example, the first work function insulating film 131 may include an aluminum oxide film (AlO).

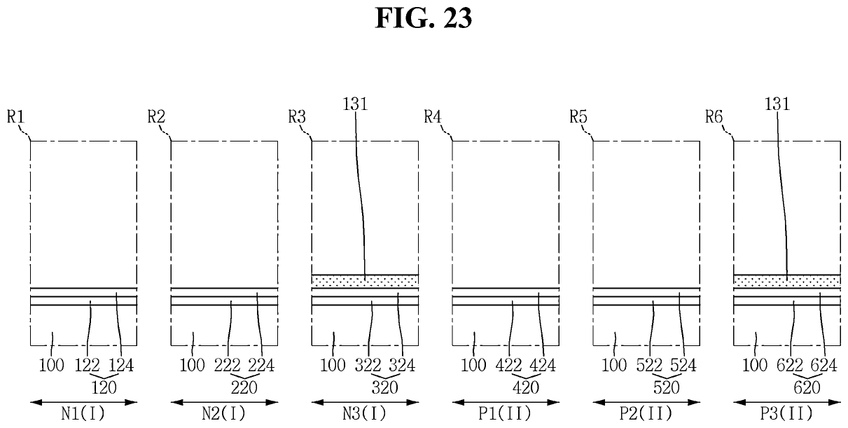

Referring to FIG. 23, a first patterning process for the first work function insulating film 131 may be performed.

As the first patterning process is performed, the first work function insulating film 131 on the first, second, fourth and fifth regions N1, N2, P1 and P2 may be removed, and the first work function insulating film 131 on the third and sixth regions N3 and P3 may remain. The first patterning process may include, for example, a photolithography process, but is not limited thereto.

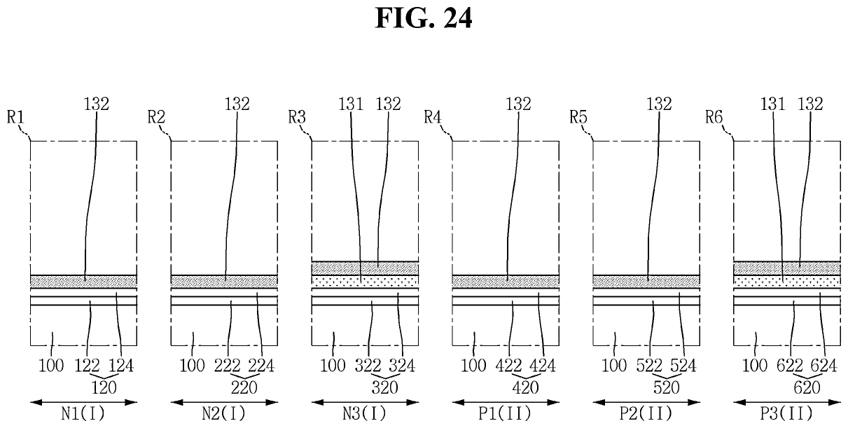

Referring to FIG. 24, a second work function insulating film 132 may be formed on the first to sixth gate dielectric films 120, 220, 320, 420, 520 and 620 and the first work function insulating film 131.

The second work function insulating film 132 may extend to be conformal along the surfaces of the first to sixth gate dielectric films 120, 220, 320, 420, 520 and 620 or a surface of the first work function insulating film 131. In one or more embodiments, the second work function insulating film 132 may include an oxide of a dipole element capable of lowering an effective work function. For example, the second work function insulating film 132 may include a lanthanum oxide film (LaO).

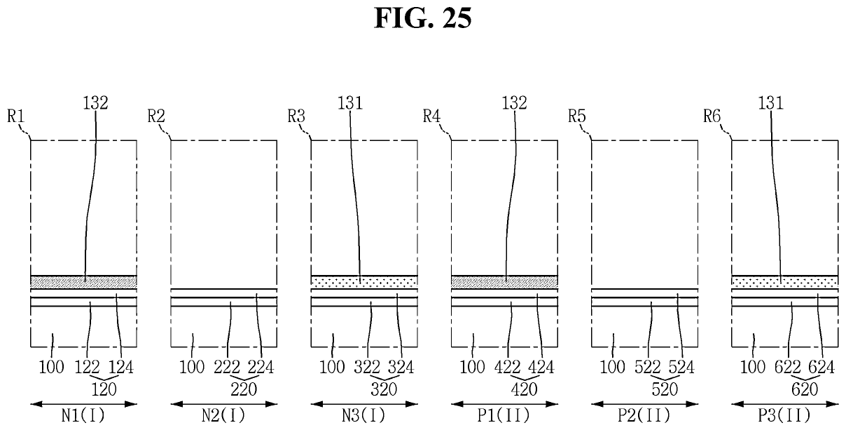

Referring to FIG. 25, a second patterning process for the second work function insulating film 132 may be performed.

As the second patterning process is performed, the second work function insulating film 132 on the second, third, fifth and sixth regions N2, N3, P2 and P3 may be removed, and the second work function insulating film 132 on the first and fourth regions N1 and P1 may remain. The second patterning process may include, for example, a photolithography process, but is not limited thereto.

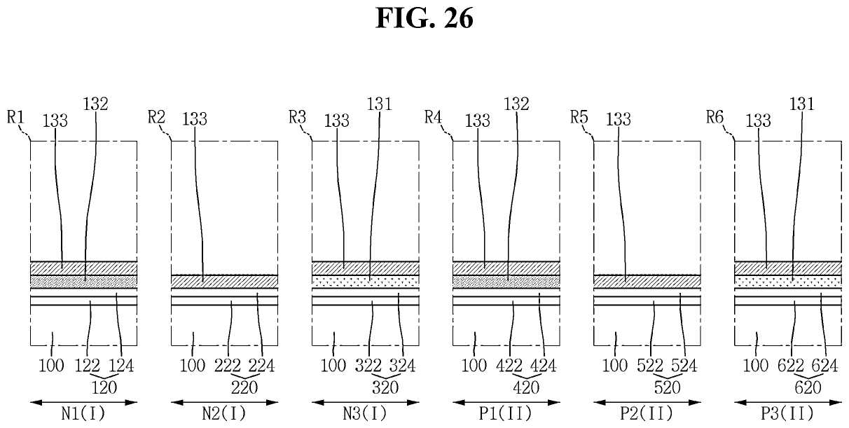

Referring to FIG. 26, a first work function conductive film 133 may be formed on the first to sixth gate dielectric films 120, 220, 320, 420, 520 and 620, the first work function insulating film 131 and the second work function insulating film 132.

The first work function conductive film 133 may extend to be conformal along the surfaces of the first to sixth gate dielectric films 120, 220, 320, 420, 520 and 620, the surface of the first work function insulating film 131 or a surface of the second work function insulating film 132.

In one or more embodiments, the first work function conductive film 133 may be a p-type work function metal film having a relatively high work function. For example, the first work function conductive film 133 may include a titanium aluminum nitride film (TiAIN).

In one or more embodiments, the first work function conductive film 133 may include the same material as that of a second work function conductive film 134 formed in a subsequent step. For example, the first work function conductive film 133 may include a titanium nitride film (TiN).

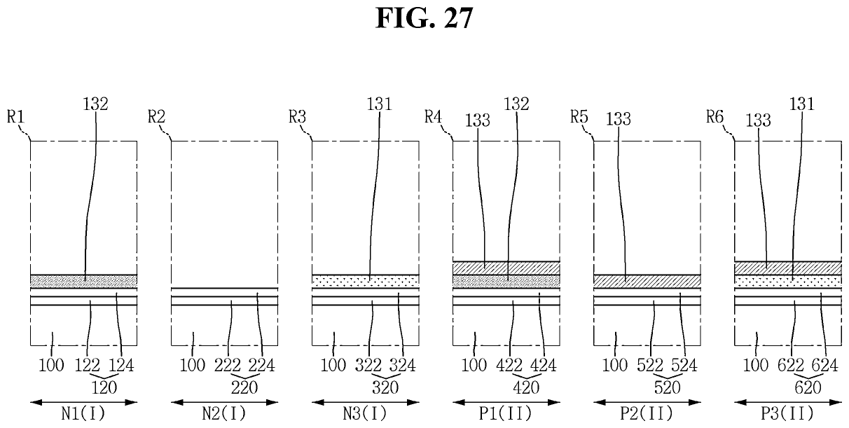

Referring to FIG. 27, a third patterning process for the first work function conductive film 133 may be performed.

As the third patterning process is performed, the first work function conductive film 133 on the N-type region I may be removed, and the first work function conductive film 133 on the P-type region II may remain. The third patterning process may include, for example, a photolithography process, but is not limited thereto.

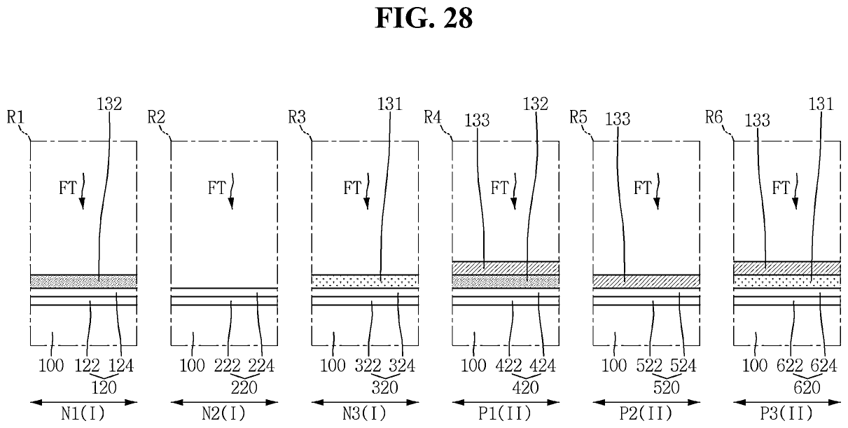

Referring to FIG. 28, a fluorine treatment process FT may be performed.

As the fluorine treatment process FT is performed, fluorine (F) may be doped into the first to sixth gate dielectric films 120, 220, 320, 420, 520 and 620, the first work function insulating film 131, the second work function insulating film 132 and/or the first work function conductive film 133.

In one or more embodiments, the fluorine treatment process FT may include a fluorine surface treatment (FST) process. For example, a heat treatment process using a fluorine-containing gas (e.g., NF3) may be performed. In the heat treatment process, fluorine (F) of the fluorine-containing gas may be dissociated to be doped from exposed surfaces on the first to sixth regions N1, N2, N3, P1, P2 and P3.

Subsequently, referring to FIG. 4, a second work function conductive film 134, a third work function conductive film 136, first to sixth capping films BL1 to BL6 and first to sixth filling films FL1 to FL6 may be sequentially formed. As a result, the semiconductor device described above with reference to FIGS. 4 to 6 may be fabricated.

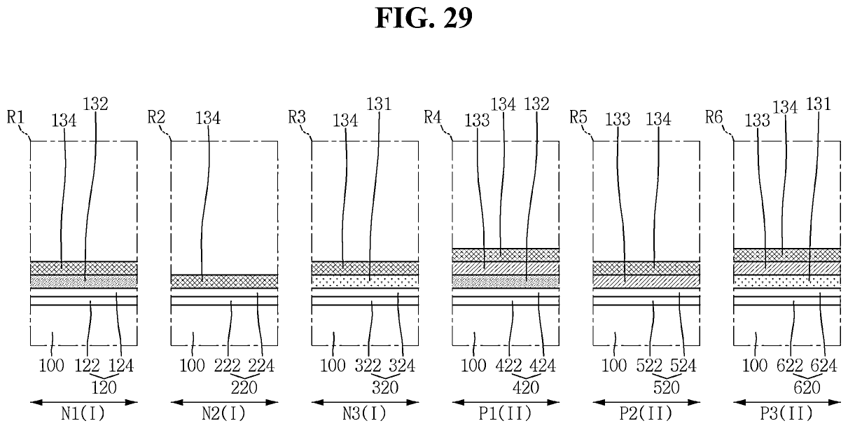

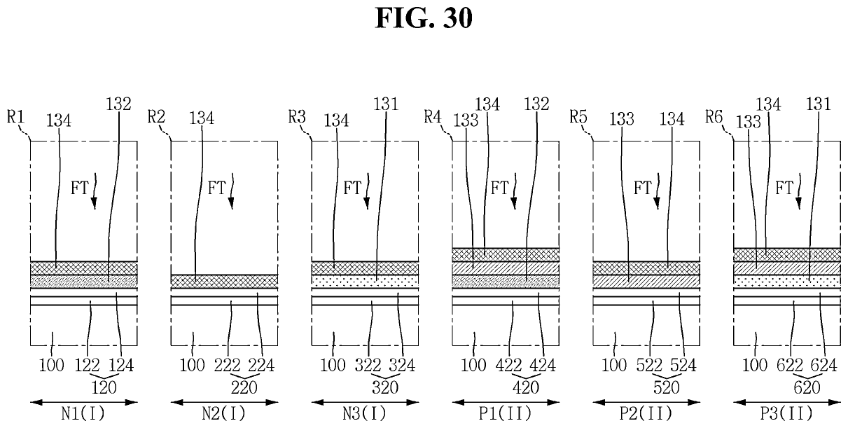

FIGS. 29 and 30 are diagrams illustrating operations of a method for fabricating a semiconductor device according to one or more embodiments. For convenience of description, redundant portions of those described above with reference to FIGS. 1 to 28 may be briefly described or omitted. For reference, FIG. 29 is a view illustrating an intermediate step subsequent to FIG. 27.

Referring to FIG. 29, the second work function conductive film 134 may be formed on the first to sixth gate dielectric films 120, 220, 320, 420, 520 and 620, the first work function insulating film 131, the second work function insulating film 132 and the first work function conductive film 133.

The second work function conductive film 134 may extend to be conformal along surfaces of the first to sixth gate dielectric films 120, 220, 320, 420, 520 and 620, a surface of the first work function insulating film 131, a surface of the second work function insulating film 132 or a surface of the first work function conductive film 133.

In one or more embodiments, the second work function conductive film 134 may be a capping metal film. For example, the second work function conductive film 134 may include a titanium nitride film (TiN).

Referring to FIG. 30, a fluorine treatment process FT may be performed.

As the fluorine treatment process FT is performed, fluorine (F) may be doped into the first to sixth gate dielectric films 120, 220, 320, 420, 520 and 620, the first work function insulating film 131, the second work function insulating film 132, the first work function conductive film 133 and/or the second work function conductive film 134. The fluorine treatment process FT is similar to that described above with reference to FIG. 28, and thus its detailed description may be omitted below.

Next, referring to FIG. 4, a third work function conductive film 136, first to sixth capping films BL1 to BL6 and first to sixth filling films FL1 to FL6 may be sequentially formed. As a result, the semiconductor device described above with reference to FIGS. 4, 7 and 8 may be fabricated.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device comprising:
a substrate comprising an N-type region and a P-type region;
a first active pattern on the N-type region;
a first gate structure on the N-type region, the first gate structure crossing the first active pattern and comprising fluorine (F);
a second active pattern on the P-type region; and
a second gate structure on the P-type region, the second gate structure crossing the second active pattern and comprising fluorine (F),
wherein the first gate structure comprises a first gate dielectric film on the first active pattern, and a first gate electrode on the first gate dielectric film,
wherein the second gate structure comprises a second gate dielectric film on the second active pattern and a second gate electrode on the second gate dielectric film, and
wherein a fluorine (F) concentration of the second gate dielectric film is smaller than a fluorine (F) concentration of the first gate dielectric film.

2. The semiconductor device of claim 1, wherein the first active pattern comprises at least one first bridge pattern spaced apart from the substrate and passing through the first gate structure, and
wherein the second active pattern comprises at least one second bridge pattern spaced apart from the substrate and passing through the second gate structure.

3. The semiconductor device of claim 1, wherein the first gate dielectric film comprises a first high dielectric film having a dielectric constant greater than a dielectric constant of silicon oxide,
wherein the second gate dielectric film comprises a second high dielectric film having a dielectric constant greater than the dielectric constant of silicon oxide, and
wherein a fluorine (F) concentration of the second high dielectric film is smaller than a fluorine (F) concentration of the first high dielectric film.

4. The semiconductor device of claim 1, wherein the first gate electrode comprises a first work function control film on the first gate dielectric film, and a first filling film on the first work function control film,
wherein the second gate electrode comprises a second work function control film on the second gate dielectric film, and a second filling film on the second work function control film, and
wherein the first filling film and the second filling film do not contain fluorine (F).

5. The semiconductor device of claim 4, wherein a thickness of the second work function control film is greater than a thickness of the first work function control film.

6. The semiconductor device of claim 4, wherein the first work function control film comprises a first work function insulating film on the first gate dielectric film, and a first work function conductive film on the first work function insulating film,
wherein the second work function control film comprises a second work function insulating film on the second gate dielectric film, and a second work function conductive film on the second work function insulating film, and
wherein a fluorine (F) concentration of the second work function insulating film is smaller than a fluorine (F) concentration of the first work function insulating film.

7. The semiconductor device of claim 6, wherein each of the fluorine (F) concentration of the second gate dielectric film and a fluorine (F) concentration of the second work function conductive film are greater than the fluorine (F) concentration of the second work function insulating film.

8. The semiconductor device of claim 1, further comprising:
a third active pattern on the P-type region; and
a third gate structure on the P-type region, the third gate structure crossing the third active pattern and comprising fluorine (F),
wherein the third gate structure comprises a third gate dielectric film on the third active pattern, and a third gate electrode on the third gate dielectric film, and
wherein a fluorine (F) concentration of the third gate electrode is different from the fluorine (F) concentration of the second gate electrode.

9. The semiconductor device of claim 8, further comprising:
a first transistor comprising the second active pattern and the second gate structure, the first transistor having a first threshold voltage; and
a second transistor comprising the third active pattern and the third gate structure, the second transistor having a second threshold voltage lower than the first threshold voltage,
wherein the fluorine (F) concentration of the third gate electrode is greater than the fluorine (F) concentration of the second gate electrode.

10. The semiconductor device of claim 9, wherein the second gate electrode comprises a first work function control film on the second gate dielectric film, and a first filling film on the first work function control film,
wherein the third gate electrode comprises a second work function control film on the third gate dielectric film, and a second filling film on the second work function control film,
wherein a fluorine (F) concentration of the second work function control film is greater than a fluorine (F) concentration of the first work function control film, and
wherein the first filling film and the second filling film do not contain fluorine (F).

11. A semiconductor device comprising:
a substrate comprising a first region and a second region;
a first transistor on the first region, the first transistor having a first threshold voltage; and
a second transistor on the second region, the second transistor having a second threshold voltage lower than the first threshold voltage,
wherein the first transistor comprises a first active pattern and a first gate structure crossing the first active pattern, the first gate structure comprising fluorine (F),
wherein the second transistor comprises a second active pattern and a second gate structure crossing the second active pattern, the second gate structure comprising fluorine (F), and
wherein a fluorine (F) concentration of the first gate structure is different from a fluorine (F) concentration of the second gate structure.

12. The semiconductor device of claim 11, wherein the first active pattern comprises at least one first bridge pattern spaced apart from the substrate and passing through the first gate structure, and
wherein the second active pattern comprises at least one second bridge pattern spaced apart from the substrate and passing through the second gate structure.

13. The semiconductor device of claim 11, wherein the first gate structure comprises a first work function control film on the first active pattern, and a first filling film on the first work function control film,
wherein the second gate structure comprises a second work function control film on the second active pattern, and a second filling film on the second work function control film, and
wherein the first filling film and the second filling film do not contain fluorine (F).

14. The semiconductor device of claim 13, wherein the first region and the second region are P-type regions, and
wherein a fluorine (F) concentration of the second work function control film is greater than a fluorine (F) concentration of the first work function control film.

15. The semiconductor device of claim 13, wherein the first region and the second region are N-type regions, and
wherein a fluorine (F) concentration of the second work function control film is smaller than a fluorine (F) concentration of the first work function control film.

16. The semiconductor device of claim 11, wherein the first gate structure comprises a first high dielectric film, a first work function insulating film and a first work function conductive film sequentially provided on the first active pattern, and
wherein a fluorine (F) concentration of the first high dielectric film and a fluorine (F) concentration of the first work function conductive film are greater than a fluorine (F) concentration of the first work function insulating film.

17. A semiconductor device comprising:
a substrate;
an active pattern on the substrate; and
a gate structure on the substrate, the gate structure crossing the active pattern and comprising fluorine (F),
wherein the gate structure comprises a high dielectric film, a work function insulating film and a work function conductive film sequentially provided on the active pattern, and
wherein a fluorine (F) concentration of the high dielectric film and a fluorine (F) concentration of the work function conductive film are greater than a fluorine (F) concentration of the work function insulating film.

18. The semiconductor device of claim 17, wherein the fluorine (F) concentration of the work function conductive film reduces as a distance to the work function insulating film decreases.

19. The semiconductor device of claim 17, wherein the fluorine (F) concentration of the high dielectric film reduces as a distance to the high dielectric film decreases.

20. The semiconductor device of claim 17, wherein the high dielectric film comprises a hafnium oxide film (HfO),
wherein the work function insulating film comprises at least one of a lanthanum oxide film (LaO) and an aluminum oxide film (AlO), and
wherein the work function conductive film comprises at least one of a titanium nitride film (TiN) and a titanium aluminum nitride film (TiAlN).
